(19) United States
(12) Patent Application Publication
(10) Pub. No.: US 2026/0031131 A1
(43) Pub. Date: Jan. 29, 2026

(54) SUB-WORD LINE DRIVER CIRCUITRY INCLUDING INTERCONNECTED CHAIN OF BLEEDER TRANSISTORS, AND RELATED DEVICES, METHODS, AND SYSTEMS

(71) Applicant: Micron Technology, Inc., Boise, ID (US)

(72) Inventor: Brenton Van Leeuwen, Boise, ID (US)

(21) Appl. No.: 19/254,932

(22) Filed: Jun. 30, 2025

Related U.S. Application Data
(60) Provisional application No. 63/676,810, filed on Jul. 29, 2024.

(51) Int. Cl. G11C 11/408

(52) U.S. Cl. CPC G11C 11/4085

(57) ABSTRACT

A device may include a number of word lines, a number of sub-word line drivers, and a number of phase signal lines. Each sub-word line driver is coupled to a main word line and a respective word line of the number of word lines. Each sub-word line driver includes a transistor. Each phase signal line is coupled to a respective gate of a respective transistor of a respective sub-word line driver of the number of sub-word line drivers. A chain of bleeder transistors is interconnected with the word lines and coupled to a negative word line voltage. The chain of bleeder transistors are biased to leak to the negative word line voltage to maintain floating word lines at the negative word line voltage.

### CROSS-REFERENCE TO RELATED APPLICATION

This application claims the benefit under 35 U.S.C. § 119 (e) of U.S. Provisional Patent Application Ser. No. 63/676,810, filed Jul. 29, 2024, the disclosure of which is hereby incorporated herein in its entirety by this reference.

### TECHNICAL FIELD

Examples of the disclosure relate to word line driver circuitry. More specifically, various examples relate to sub-word line driver circuitry including interconnected chains of bleeder transistors, and related devices, methods, and systems.

### BACKGROUND

Memory devices are typically provided as internal, semiconductor, integrated circuits in computers or other electronic systems. There are many different types of memory including, for example, random-access memory (RAM), read-only memory (ROM), dynamic random-access memory (DRAM), synchronous dynamic random-access memory (SDRAM), resistive random-access memory (RRAM), double data rate memory (DDR), low-power double data rate memory (LPDDR), phase change memory (PCM), and Flash memory.

Memory devices typically include many memory cells that are capable of holding a charge that is representative of a bit of data. Typically, these memory cells are arranged in a memory array. Data may be written to or retrieved from a memory cell by selectively activating the memory cell via an associated word line driver.

### BRIEF DESCRIPTION OF THE DRAWINGS

FIG. 1 is a schematic block diagram depicting a memory system which may embody one or more examples of the disclosure;

FIG. 2 is a schematic block diagram depicting a memory device which may embody sub-word driver (SWD) circuitry according to one or more examples of the disclosure;

FIG. 3 is a diagram of an SWD including a single transistor which may be utilized in SWD circuitry of one or more examples;

FIG. 4 is a signal diagram of control signals which may be used to control SWDs including the single transistor (e.g., the SWD of FIG. 3);

FIG. 5 is a schematic diagram of SWD circuitry including single transistor technology which may be employed in one or more examples;

FIGS. 6A and 6B are schematic diagrams depicting SWD circuitry which may be utilized in one or more examples;

FIG. 7 is a diagram indicating various states of a number word lines in an example operating scenario according to one or more examples;

FIG. 8 is a schematic diagram of SWD circuitry which may be utilized in one or more examples of the disclosure;

FIG. 9 is a layout of SWD circuitry including a number of SWD transistors of FIG. 8;

FIG. 10 is a schematic diagram of SWD circuitry including a chain of bleeder transistors, according to one or more examples of the disclosure;

FIG. 11 is a layout of the SWD circuitry including the chain of bleeder transistors of FIG. 10 according to one or more examples of the disclosure;

FIG. 12 is a circuit portion of SWD circuitry of FIG. 10 in an example operating scenario according to one or more examples of the disclosure;

FIG. 13 is a flowchart of a method of operating SWD circuitry according to one or more examples of the disclosure;

FIG. 14 is a simplified block diagram of a memory device according to one or more examples of the disclosure; and

FIG. 15 is a simplified block diagram of an electronic system according to one or more examples of the disclosure.

### DETAILED DESCRIPTION

Memory typically includes many memory cells arranged in a two-dimensional array of intersecting rows and columns. Data is written to or retrieved from the memory cells by selectively applying activation voltages to word lines (i.e., access lines) and bit lines (i.e., data lines). In general, word lines activate memory cells and bit lines provide data to or retrieve data from the activated memory cells. When memory access is desired, an activation voltage may be applied to a word line by a word line driver to enable a desired function (e.g., read or write) to be performed. More particularly, when an activation voltage (e.g., a high voltage) is applied via a word line, circuitry (e.g., a passgate transistor) in a memory cell may enable a bit line to write data to or retrieve data from the activated memory cell. When memory access is not needed, the word line driver may apply a deactivation voltage (e.g., a low voltage or ground voltage).

In some memory devices and systems, a number of sub-word line drivers that each include a single (e.g., only one) transistor may be utilized to drive the word lines. The transistor of the sub-word line driver is coupled to a main word line signal driven by a main word line driver of a memory device and translates this signal to a word line corresponding to a memory cell matrix. The transistor may further be coupled to a phase signal configured to selectively activate the transistor to couple the word line to the main word line signal via the transistor. For example, the word line may be included in a first set of word lines that are each coupled to the same main word line signal via a transistor of a corresponding sub-word line driver. A second set of word lines that correspond to the memory cell matrix may be coupled to a different main word line signal and interleaved with the word lines of the first set.

When one of the word lines of the first set is selected and fired (e.g., for memory operations), the other word lines of the first set may be floated. The word lines of the second set may be used to shield the floating, unselected word lines of the first set from the selected and fired word line of the first set. In at least some cases, however, potential memory array defects could cause some of the floating, unselected word lines to be sourced high enough to cause data corruption.

The technology of the disclosure may be built upon, or based on, the single-transistor, sub-word line driver circuitry, or variations thereof, to improve the performance and/or reliability of such circuitry.

According to one or more examples, a chain of bleeder transistors is interconnected with the word lines and coupled to a low voltage associated with a low voltage state. In a specific, non-limiting example, the low voltage is a negative word line voltage. In one or more examples, the chain of bleeder transistors is biased to leak to the negative word line voltage to maintain floating word lines at the negative word line voltage. In the chain, a majority of the bleeder transistors are coupled between respective pairs of word lines associated with adjacent sub-word line drivers. In one or more examples, the chain of bleeder transistors may include at least one terminating bleeder transistor coupled between one of the word lines and the negative word line voltage (e.g., at an end of the chain).

The memory devices and systems of the disclosure are primarily described in the context of devices incorporating DRAM storage media. Memory devices configured in accordance with other examples of the disclosure, however, may include other types of memory devices and systems incorporating other types of storage media, including PCM, SRAM, SDRAM, DDR SDRAM, SGRAM, FRAM, RRAM, MRAM, read-only memory (ROM), erasable programmable ROM (EPROM), electrically erasable programmable ROM (EEROM), ferroelectric, magnetoresistive, and other storage media, including non-volatile (e.g., flash, NAND and/or NOR) storage media. Although various examples are described herein with reference to memory devices, the present disclosure is not so limited, and the examples may be generally applicable to microelectronic devices that may or may not include semiconductor devices and/or memory devices. A person skilled in the art will readily appreciate that the technology may have variations and that the technology may be practiced without use of several of the details in the examples described below.

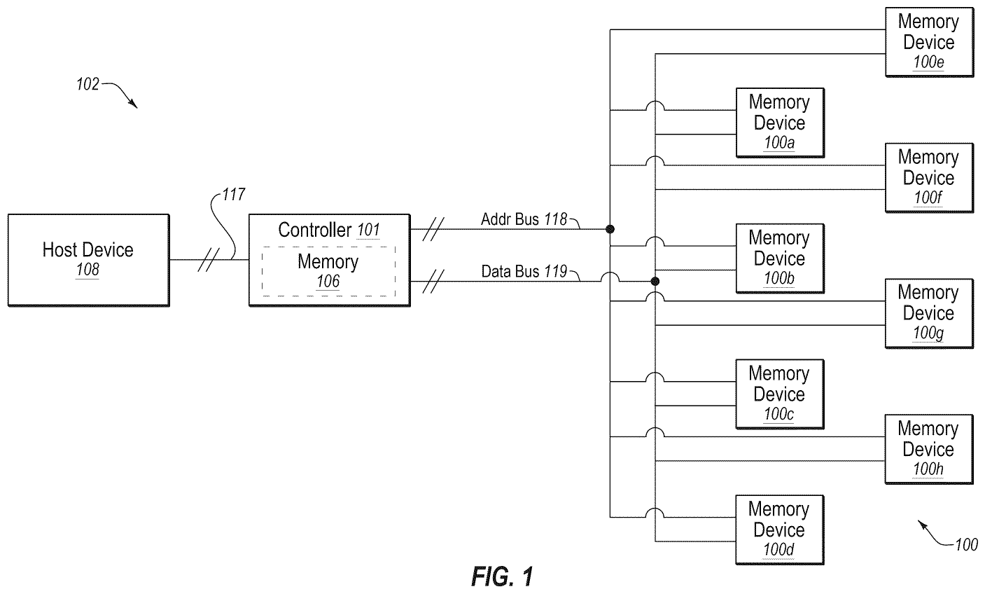

FIG. 1 is a schematic block diagram depicting a memory system 102 which may embody one or more examples of the disclosure. In one or more examples, memory system 102 is a dual in-line memory module (DIMM). Memory system 102 includes a number of memory devices 100 including memory devices 100a, 100b, 100c, 100d, 100e, 100f, 100g, and 100h. In one or more examples, memory devices 100 may be DRAM memory devices. Although illustrated with eight memory devices 100 in FIG. 1, memory system 102 may include a greater or lesser number of memory devices 100 in one or more other examples.

Memory devices 100 may be connected to one or more electronic devices that are capable of utilizing memory for temporary or persistent storage of information, or a component thereof. For example, one or more of memory devices 100 may be operably connected to one or more host devices. In a specific, non-limiting example, memory devices 100 of memory system 102 may be connected to a host device, such as a memory controller 101, which is connected to host device 108.

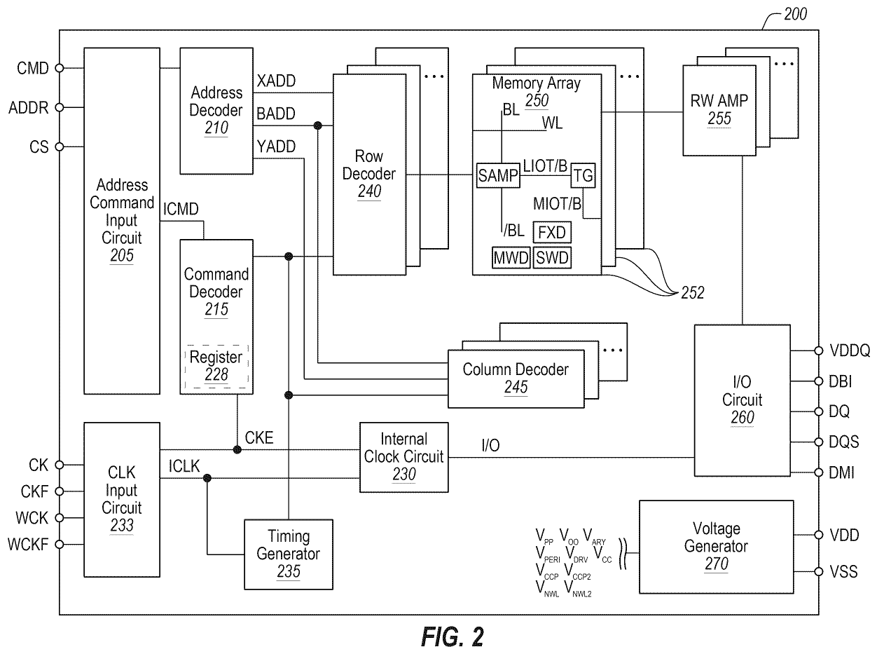

In one or more examples, memory devices 100 of FIG. 1 may be operably connected to memory controller 101 via a command/address (CMD/ADDR) bus 118 (hereinafter “address bus 118”) and a data (DQ) bus 119 (hereinafter “data bus 119”). As described in detail later below in relation to FIG. 2, address bus 118 and data bus 119 may be used by memory controller 101 to communicate commands, memory addresses, and/or data to memory devices 100. In response, memory devices 100 may execute commands received from memory controller 101. For example, in the event a write command is received from memory controller 101 over address bus 118, memory devices 100 may receive data from memory controller 101 over data bus 119 and may write the data to memory cells corresponding to memory addresses received from the memory controller 101 over address bus 118. As another example, in the event a read command is received from memory controller 101 over address bus 118, memory devices 100 may output data to memory controller 101 over data bus 119 from memory cells corresponding to memory addresses received from memory controller 101 over address bus 118.

In FIG. 1, memory controller 101 includes a memory 106 configured to store various processes, logic flows, and routines for controlling operation of memory system 102, including managing memory devices 100 and handling communications between memory devices 100 and host device 108. In one or more examples, memory 106 may include memory registers storing, for example, memory pointers, fetched data, etc. Memory 106 may also include read-only memory (ROM) or other non-volatile memory, and/or volatile memory (e.g., SRAM). Although shown embedded in memory controller 101 in FIG. 1, memory 106 may be positioned at other locations in memory system 102 in other examples of the disclosure, such as exterior memory controller 101, host device 108, and/or one or more of memory devices 100a, 100b, 100c, 100d, 100e, 100f, 100g, and 100h.

In one or more examples, host device 108 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). Host device 108 may be a networking device (e.g., a switch, a router, etc.); a recorder of digital images, audio, and/or video; a vehicle; an appliance; a toy; or any one of a number of other products. In one embodiment, host device 108 may be connected directly to one or more of memory devices 100 (e.g., via a communications bus of signal traces, not shown). Additionally, or alternatively, host device 108 may be indirectly connected to one or more of memory devices 100 (e.g., over a networked connection or through intermediary devices, such as through memory controller 101 and/or via a communications bus 117 of signal traces).

FIG. 2 is a schematic block diagram depicting a memory device 200 which may embody write driver circuitry according to one or more examples of the disclosure. Memory device 200 of FIG. 2 may be a specific example of any one of memory devices 100a, 100b, 100c, 100d, 100e, 100f, 100g, and 100h of FIG. 1. Memory device 200 may include an array of memory cells, such as a memory array 250. Memory array 250 may include a number of memory banks 252 (e.g., four banks, eight banks, sixteen banks, thirty-two banks, or any other number of memory banks), and each memory bank 252 may include a number of word lines (WLs), a number of bit lines (BLs), and a number of memory cells (e.g., m×n memory cells) arranged at intersections of the word lines (e.g., m word lines, which may also be referred to as memory rows) and the bit lines (e.g., n bit lines, which may also be referred to as memory columns). Memory array 250 (e.g., each memory bank 252) may be divided into smaller sections or subarrays, and the subarrays may be split into memory cell matrices (MATs). Memory cells of memory array 250 may include any one of a number of different memory media types, including capacitive, phase change, magnetoresistive, ferroelectric, or the like.

Memory array 250 further includes main word line drivers (MWDs) (also referred to herein as “global word line drivers”), sub-word line drivers (SWDs) (also referred to herein as “local word line drivers”), and phase drivers (FXDs). The MWDs, SWDs, and FXDs are coupled to corresponding word lines WLs, and are configured to control voltage levels on the corresponding word lines WLs during memory operations. For example, each word line WL may be coupled to one or more main rows or main word lines that are each driven by a corresponding MWD. More specifically, each main word line driven by a MWD may be coupled to eight SWDs, sixteen SWDs, or some other desired number of SWDs, and each of the SWDs and FXDs may be coupled to corresponding word lines WLs (e.g., local word lines) of one or more of the subarrays and/or one or more of the memory cell MATs of memory array 250. The SWDs may be used in combination with the MWDs and FXDs to control voltage levels on the corresponding word lines WLs. Along with the MWDs, the FXDs provide phase signals (PHs) to the SWDs to select SWDs for memory operations based on decoded row address signals and timing control signals.

The selection of a word line WL for memory operations may be performed by a row decoder 240, and the selection of a bit line BL (and/or a bit line/BL) for memory operations may be performed by a column decoder 245. In FIG. 2, row decoder 240 includes a respective row decoder for each memory bank 252, and column decoder 245 includes a respective column decoder for each memory bank 252. Sense amplifiers (SAMP) may be provided for corresponding bit lines BL and/BL and may be connected to at least one respective local I/O line pair (LIOT/B) that, in turn, may be coupled to at least one respective main I/O line pair (MIOT/B) via transfer gates (TG) that may function as switches. Read data from the bit line BL or the bit line/BL is amplified by the sense amplifier SAMP, and transferred to read/write amplifiers 255 over the local I/O line pair, the transfer gates TG, and the main I/O line pair MIOT/B. Write data output from read/write amplifiers 255 is transferred to the sense amplifier SAMP over the main I/O line pair MIOT/B, the transfer gates TG, and the local I/O line pair LIOT/B, and thereafter written in or stored to a memory cell coupled to the bit line BL or the bit line/BL.

Memory device 200 may employ a number of external terminals that include command and address terminals coupled to a command/address bus (e.g., address bus 118 of FIG. 1) to receive command signals CMD and address signals ADDR, respectively. Memory device 200 may further include a chip select terminal to receive a chip select signal CS; clock terminals to receive clock signals CK and/or CKF; data clock terminals to receive data clock signals WCK, WCKF, and/or DQS; data terminals DQ, DBI (for data bus inversion function), and/or DMI (for data mask inversion function); and/or power supply terminals VDD, VSS, VDDQ, and/or VSSQ (not shown).

The power supply terminals may be supplied with power supply potentials VDD and VSS. These power supply potentials VDD and VSS may be supplied to an internal voltage generator circuit 270. Internal voltage generator circuit 270 may generate various internal potentials VPP, VOD, VARY, VPERI, VNWL, VNWL2, VDRV, VCC, VCCP, VCCP2, and the like based on the power supply potentials VDD and VSS. In one or more examples, one or more of the internal potentials may be externally supplied to memory device 200, and/or some of the internal potentials may be generated by other circuits of memory device 200 (instead of voltage generator circuit 270) based on, for example, the power supply potentials VDD and VSS.

The internal potential VPP may be used in row decoder 240, the internal potentials VOD and VARY may be used in the sense amplifiers included in memory array 250, and the internal potential VPERI may be used in various circuit blocks of memory device 200. The negative word line voltage VNWL, the negative word line voltage VNWL2, the driver voltage VDRV, the common collector voltage VCC, the common collector pumped voltage VCCP, and/or the common collector pumped voltage VCCP2 may be used, for example, in memory array 250, such as by the MWDs, the SWDs, and/or the FXDs. In one or more examples, the common collector voltage VCC may be in a range from about 2.3 volts to 2.7 volts (e.g., 2.5 volts); the common collector pumped voltage VCCP may be in a range from about 3.0 volts to about 3.5 voltage (e.g., 3.3 volts); and the common collector pumped voltage VCCP2 may be in a range from about 4.0 volts to about 4.5 volts (e.g., 4.2 volts). In these and other embodiments, the driver voltage VDRV may be in a range from about 1.5 volts to about 2.0 volts (e.g., 1.9 volts), and the negative word line voltage VNWL may be in a range from about −0.1 volts to about −0.25 volts (e.g., −0.15 volts); the negative word line voltage VNWL2 may be made slightly lower than VNWL.

The power supply terminals may also be supplied with power supply potentials VDDQ and/or VSSQ (not shown). The power supply potentials VDDQ and VSSQ may be supplied to an input/output circuit 260 together with the power supply potentials VDD and VSS. The power supply potentials VDDQ and VSSQ may be the same potentials as the power supply potentials VDD and VSS, respectively, in some embodiments of the present technology. The power supply potentials VDDQ and VSSQ may be different potentials from the power supply potentials VDD and VSS, respectively, in other embodiments of the present technology. The power supply potentials VDDQ and VSSQ may be used for input/output circuit 260 so that power supply noise generated by input/output circuit 260 does not propagate to the other circuit blocks of memory device 200.

The external clock signals CK and CKF received at the clock terminals and/or the external data clock signals WCK and WCKF received at the data clock terminals may be supplied to a clock input circuit 233. For example, when enabled by a clock enable signal CKE, input buffers included in clock input circuit 233 may receive the clock signals CK and CKF and/or the data clock signals WCK and WCKF. The CK and CKF signals may be complementary, and/or the WCK and WCKF signals may be complementary.

Clock input circuit 233 may generate an internal clock signal ICLK based on the clock signals CK, CKF, WCK, and/or WCKF. The internal clock signal ICLK signal may be supplied to an internal clock circuit 230. In turn, internal clock circuit 230 may provide various phase and frequency controlled internal clock signals based on the internal clock signals ICLK and/or the clock enable signal CKE. The phase and frequency controlled internal clock signals may be used for timing operation of various internal circuits of memory device 200. For example, internal clock circuit 230 may provide input/output clock signals I/O to input/output circuit 260 of memory device 200. The input/output clock signals I/O may be used as timing signals for determining an output timing of read data and/or an input timing of write data. The input/output clock signals I/O may be provided at multiple clock frequencies so that data may be output from and/or input into memory device 200 at different data rates. A higher clock frequency may be desirable when high memory speed is desired. A lower clock frequency may be desirable when lower power consumption is desired. The internal clock signals ICLK may additionally or alternatively be supplied to a timing generator 235 (e.g., to generate various internal clock signals) and/or to a command decoder 215.

The command/address terminals may be supplied with addresses signals ADDR from outside memory device 200 (e.g., from a memory controller). The address signals ADDR supplied to the address terminals may be transferred, via command/address input circuit 205, to an address decoder 210. Address decoder 210 may receive the address signals ADDR and supply a decoded row address signal (XADD) to row decoder 240, and a decoded column address signal (YADD) to the column decoder 245. Address decoder 210 may also supply a decoded bank address signal (BADD) to row decoder 240 and to column decoder 245. The decoded bank address signal (BADD) may specify a memory bank 252 of memory array 250 containing the decoded row address XADD and the decoded column address YADD.

The command/address terminals may further be supplied with command signals CMD and/or chip select signals CS from outside memory device 200. The command signals may represent various memory commands (e.g., refresh commands; activate commands; precharge commands; access commands, such as read commands and write commands; timing commands; etc.) from a memory controller. The access commands may be associated with one or more row addresses XADD, column addresses YADD, and bank addresses BADD to indicate which memory cells of memory array 250 to access. The chip select signal CS may be used to select memory device 200 to respond to commands and addresses provided to the command and address terminals of memory device 200. When an active CS signal is provided to memory device 200, the commands and addresses may be decoded and memory operations may be performed. When the CS signal is not active, memory device 200 may ignore commands and/or addresses provided to the command and address terminals.

The command signals CMD received at the command terminals may be supplied to command decoder 215, via command/address input circuit 205, as internal command signals ICMD. Command decoder 215 may include circuits to decode the internal command signals ICMD and generate various internal signals and commands for performing memory operations. For example, command decoder 215 may provide a row command signal to select a word line and a column command signal to select a bit line (e.g., in response to receiving an access command). Other examples of memory operations that memory device 200 may perform based on decoding the internal command signals ICMD include refresh commands (e.g., re-establishing full charges stored in individual memory cells of memory array 250), activate commands (e.g., activating a row in a particular memory bank 252, in some cases for subsequent access operations), or precharge commands (e.g., deactivating the activated row in particular memory bank 252).

In one or more examples, command decoder 215 may further include one or more registers 228 for tracking various counts and/or values (e.g., counts of refresh commands received by memory device 200 or self-refresh operations performed by memory device 200) and/or for storing various operating conditions for memory device 200 to perform certain functions, features, and modes (or test modes). In one or more examples, registers 228 (or a subset of the registers 228) may be referred to as mode registers. Additionally, or alternatively, memory device 200 may include registers 228 as a separate component outside of command decoder 215. In one or more examples, registers 228 may include multi-purpose registers (MPRs) configured to write and/or read specialized data to and/or from memory device 200.

When a read command is issued to a memory bank 252 with an open row and a column address is timely supplied as part of the read command, read data may be read from memory cells in memory array 250 designated by the row address (which may have been provided as part of the activate command identifying the open row) and the column address. The read command may be received by command decoder 215, which may provide internal commands so that read data from memory array 250 is output from memory device 200 via read/write amplifiers 255 and input/output circuit 260, using the data terminals DQ, DBI, and/or DMI, and/or according to the DQS clock signal. The read data may be provided at a time defined by read latency information that may be programmed in memory device 200, for example, in a mode register (e.g., one or more of registers 228). The read latency information may be defined in terms of clock cycles of the CK clock signal. For example, the read latency information may be a number of clock cycles of the CK signal after the read command is received by memory device 200 when the associated read data is provided.

When a write command is issued to a memory bank 252 with an open row and a column address is timely supplied as part of the write command, write data may be supplied to the data terminals DQ, DBI, and/or DMI. The write data may be supplied to the data terminals DQ, DMI, and/or DMI according to the WCK and WCKF clock signals. The write command may be received by command decoder 215, which may provide internal commands to input/output circuit 260 so that the write data may be received by data receivers in input/output circuit 260 and supplied to memory array 250 via read/write amplifiers 255. The write data may be written in the memory cell designated by the row address and the column address. The write data may be provided to the data terminals at a time that is defined by write latency WL information. The write latency WL information may be programmed in memory device 200, for example, in a mode register (e.g., one or more of registers 228). The write latency WL information may be defined in terms of clock cycles of the CK clock signal. For example, the write latency information WL may be a number of clock cycles of the CK signal after the write command is received by the memory device 200 when the associated write data is received.

As described above, SWDs may be used in combination with MWDs to drive voltages onto word lines WLs for memory operations. For example, a two-transistor SWD may be coupled to a main word line signal that is driven by an MWD. When a word line WL corresponding to the SWD is selected for memory operations, a first transistor (e.g., a pull-up transistor) of the SWD may be activated to couple the word line WL to the main word line signal that ramps the voltage on the word line WL to a high voltage which is driven by the MWD. Activation of the first transistor may be controlled by a first FXD. When an adjacent word line WL (e.g., a word line WL of a same memory cell matrix) is selected, a second transistor (e.g., a pull-down transistor) of the SWD may be activated to couple the word line WL to a low voltage line to drop the voltage on the word line WL. Activation of the second transistor may be controlled by a second FXD. In other words, the SWD may be used to ramp the corresponding word line WL to a high voltage when the word line WL is selected for memory operations, and to drop the word line WL to a low voltage when adjacent local word lines are selected for memory operations.

The multiple transistor arrangement of the NMOS SWD consumes a relatively large amount of space, especially as the SWD is replicated for every word line across a memory array. Furthermore, the multiple transistor arrangement of the NMOS SWD utilizes multiple FXDs to selectively activate the transistors. Using multiple FXDs per SWD also consumes a relatively large amount space and a relatively large amount of power.

To address the above issues, memory devices and systems have been developed using NMOS sub-word line drivers having a single (e.g., only one) transistor. Such technology is described in application Ser. No. 17/894,089, filed on Aug. 23, 2022, portions of which are repeated herein for completeness. In one or more examples, the technology of the present disclosure is built upon, or based on, this single-transistor, sub-word line driver circuitry, or variations thereof, for improving the performance and/or reliability of such technology. In one or more other examples, the technology of the present disclosure may be built upon, or based on, a different type of sub-word line driver technology.

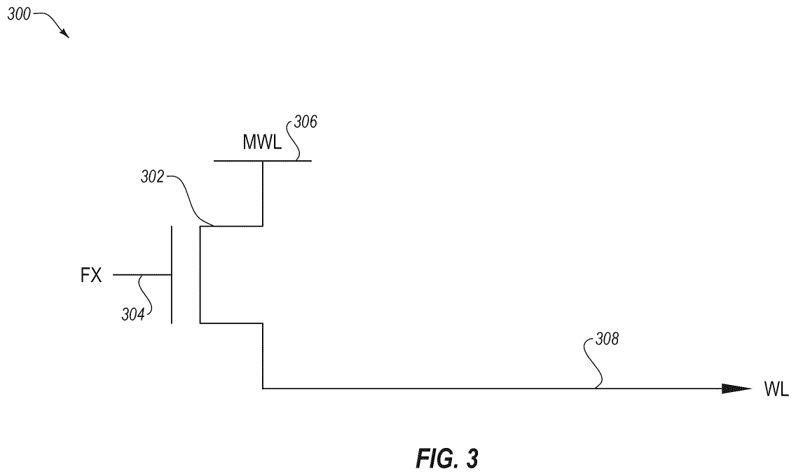

FIG. 3 is a diagram of an SWD 300 including a single NMOS transistor which may be utilized in SWD circuitry of one or more examples of the disclosure. In the example of FIG. 3, SWD 300 includes a transistor 302. Transistor 302 of SWD 300 may be a single (e.g., and only) transistor of SWD 300. In one or more examples, transistor 302 may be an NMOS transistor. In FIG. 3, transistor 302 includes a first terminal (e.g., a source or a drain) coupled to a main word line 306 (MWL, or MWL 0/1), a second terminal (e.g., a drain or a source) coupled to a word line 308, and a gate coupled to a phase signal line (FX, or FX 0/1) 304 of a phase driver (FXD). Main word line 306 may be one of a first MWL (e.g., MWL0) or a second MWL (e.g., MWL1), and phase signal 304 may be one of a first FX (e.g., FX0) or a second FX (e.g., FX2).

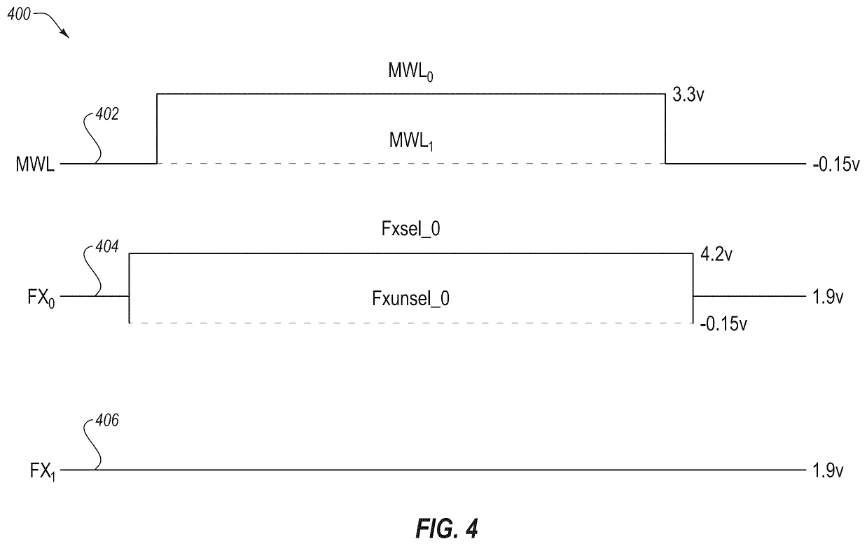

FIG. 4 is a signal diagram of control signals 400 which may be used to control SWDs including single transistor technology (e.g., SWD 300 of FIG. 3). Control signals 400 include MWL voltage signal levels 402 associated with MWL 306 of FIG. 3, phase signal voltage levels 404 (FX₀) associated with FX 304 of FIG. 3 when MWL 306 is in a high state, and a phase signal voltage level 406 (FX₁) associated with FX 304 of FIG. 3 when MWL 306 is in a low state. In the example of FIG. 4, MWL voltage signal levels 402 indicate a high state voltage of about 3.3 volts (e.g., associated with MWL0) and a low state voltage of about −0.15 volts (e.g., associated with MWL1). Phase signal voltage levels 404 (FX₀ or PH0) indicate a high state voltage (or “select”) of about 4.2 volts and a low state voltage (or “unselect”) of about −0.15 volts. Phase signal voltage level 406 (FX₁ or PH1) indicates a precharge voltage of about 1.9 volts.

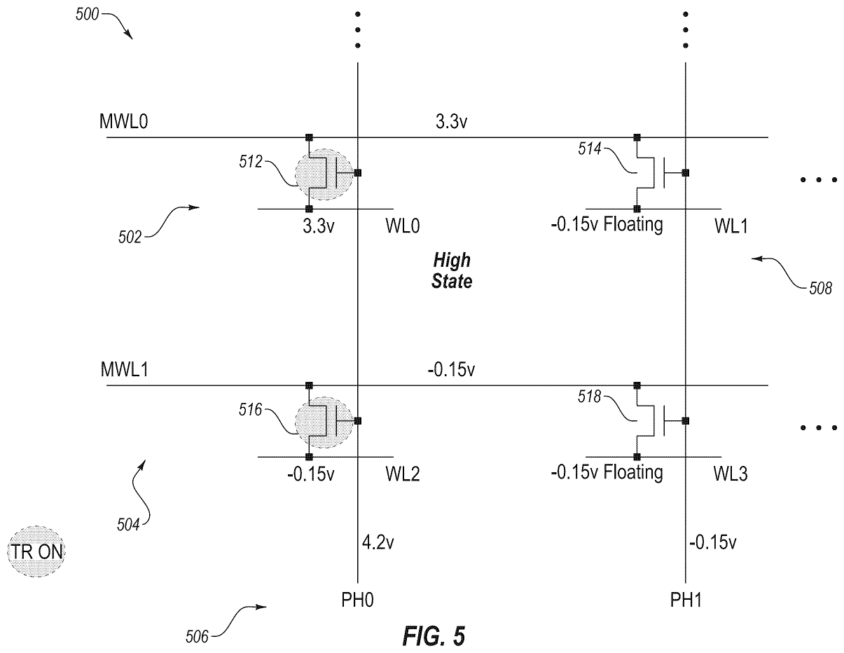

FIG. 5 is a schematic diagram of SWD circuitry 500 including single transistor technology which may be utilized in one or more examples of the disclosure. SWD circuitry 500 includes a number of SWD transistors 502, a number of main word lines 504, a number of phase signal lines 506, and a number of word lines 508. The number of SWD transistors 502 include SWD transistors 512, 514, 516, and 518. In one or more examples, each one of SWD transistors 502 may be the same or similar to SWD 300 including transistor 302 of FIG. 3 and/or controlled by control signals 400 of FIG. 4. The number of phase signal lines 506 include a phase signal line PH0 and a phase signal line PH1. The number of main word lines 504 include a main word line MWL0 and a main word line MWL1. MWL signals are doubled so that even and odd SWD gaps may be driven independently. The number of word lines 508 include word lines WL0, WL1, WL2, and WL3.

In FIG. 5, a first terminal (e.g., a source or a drain) of SWD transistor 512 and a first terminal (e.g., a source or a drain) of SWD transistor 514 are coupled to main word line MWL0. A second terminal (e.g., a drain or a source) of SWD transistor 512 is coupled to word line WL0 and a second terminal (e.g., a drain or a source) of SWD transistor 514 is coupled to word line WL1. A first terminal (e.g., a source or a drain) of SWD transistor 516 and a first terminal (e.g., a source or a drain) of SWD transistor 518 are coupled to main word line MWL1. A second terminal (e.g., a drain or a source) of SWD transistor 516 is coupled to word line WL2 and a second terminal (e.g., a drain or a source) of SWD transistor 518 is coupled to word line WL3. A gate of SWD transistor 512 and a gate of SWD transistor 516 are coupled to phase signal line PH0. A gate of SWD transistor 514 and a gate of SWD transistor 518 are coupled to phase signal line PH1.

In FIG. 5, control signals are used to control SWD circuitry 500 to turn on SWD transistor 512 to set word line WL0 to a high state. To activate word line WL0, the main word line MWL0 is set to a high state (e.g., about 3.3 volts) and the main word line MWL1 is set to a low state (e.g., about −0.15 volts); the phase signal line PH0 is set to a high state (e.g., about 3.3 volts) and the phase signal line PH1 is set to a low state (e.g., about −0.15 volts). As the main word line MWL0 is at the high state and SWD transistor 512 is switched to turn on (PH0=high state), the word line WL0 is set to the high state voltage of the main word line MWL0. As the main word line MWL1 is at the low state and SWD transistor 516 is switched to turn on (PH0=high state), the word line WL2 is set to the low state voltage of the main word line MWL1. On the other hand, SWD transistor 514 and SWD transistor 518 remain off (PH1=low state) and therefore the word line WL1 and the word line WL3 remain floating at the low state (e.g., about −0.15 volts).

As is apparent, SWD transistor 512 is selectively activated in response to a high voltage on phase signal line PH0 when main word line MWL0 is at the high state. In this arrangement, only a single-phase signal is utilized to activate SWD transistor 512. In comparison to SWDs having multiple transistor arrangements, SWDs having single transistor arrangements may have a relatively smaller footprint (e.g., through use of the single transistor and/or a single-phase signal per sub-word line driver) and may consume less power (e.g., through use of the single phase signal per sub-word line driver). Such reduction in size improves array efficiency (AE) (i.e., a metric commonly used to evaluate at least some memory devices (e.g., DRAM devices)).

More generally, word lines of a memory cell matrix may be electrically coupled to one of two main word lines. For example, a first set of word lines may be coupled to a first main word line, and a second set of word lines may be coupled to a second main word line. Word lines of the first set may be interleaved with word lines of the second set in the memory cell mat. Using two main word lines instead of one main word line allows at least some unselected word lines of the memory cell matrix to be floated. More specifically, when a word line of one of the sets is selected and fired, the other word lines of that set may be floated, and word lines of the other set may be dropped to a low voltage to shield the floating word lines from coupling noise with the fired word line. Floating at least some of the unselected word lines rather than dropping all of the unselected word lines to a low voltage helps reduce the power consumed by a memory device incorporating such sub-word line drivers. It is desirable to ensure that the floating, unselected word lines are not adversely affected so as to cause data corruption.

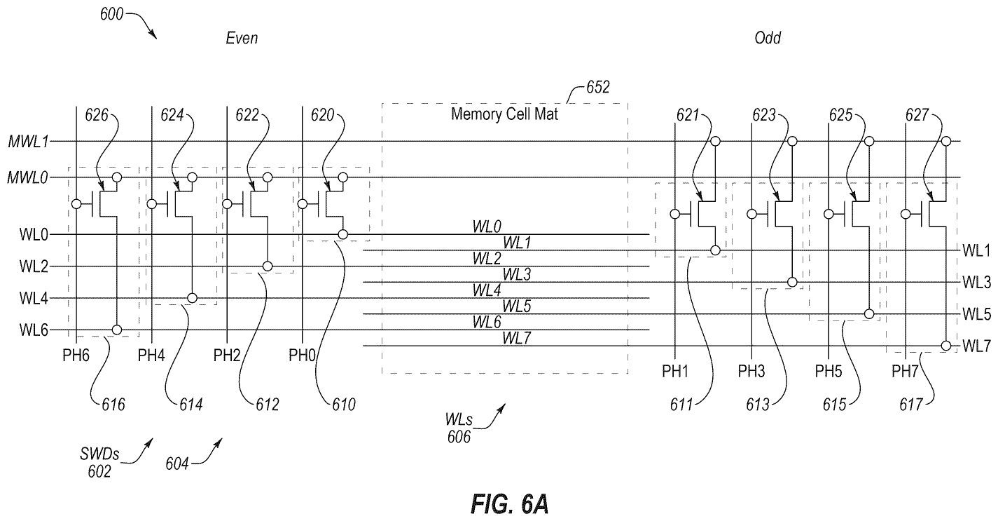

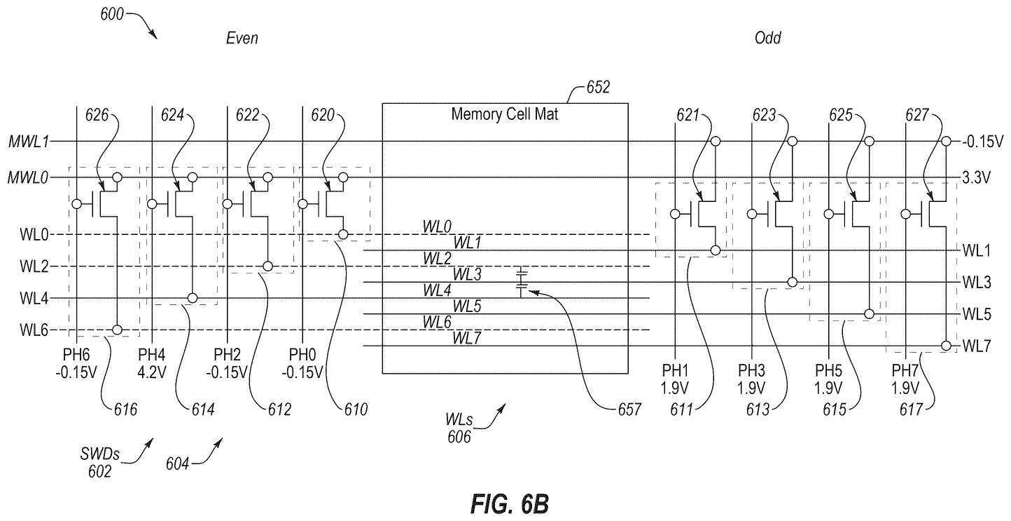

FIGS. 6A and 6B are schematic diagrams depicting SWD circuitry 600 which may be utilized in one or more examples of the disclosure. SWD circuitry 600 includes a number of sub-word line drivers (SWDs) 602. In FIG. 6A, the number of SWDs 602 include SWDs 610, 612, 614, and 616 (i.e., even numbered SWDs) and SWDs 611, 613, 615, and 617 (i.e., odd numbered SWDs). As shown, each one of SWDs 602 is coupled to a corresponding one of a number of phase signal lines (PH) 604 and a corresponding one of a number of word lines (WLs) 606 of a memory cell MAT 652. The number of word lines 606 may be alternatively referred to as local word lines. In FIG. 6A, the number of word lines 606 include WL0, WL2, WL4, and WL6 (i.e., even numbered word lines) and WL1, WL3, WL5, and WL7 (i.e., odd numbered word lines). Phase signal lines 604 include the phase signal lines PH0, PH2, PH4, and PH6 (i.e., even numbered phase signal lines) and PH1, PH3, PH5, and PH7 (i.e., odd numbered phase signal lines). Each of the phase signal lines PH0-PH7 may be driven by a corresponding phase driver FXD (not shown).

In one or more examples, the number of word lines 606 (e.g., WL0-WL7) terminate at or proximate memory cell MAT 652. Stated another way, word lines 606 do not pass through to the (global) memory array (e.g., memory array 250 of FIG. 2). As discussed above, such a configuration of word lines is easier and less costly to fabricate or manufacture than a pass-through configuration of word lines. In one or more alternative examples, the word lines may pass through to the memory array.

Each one of SWDs 602 may be further coupled to one of two main word lines MWL0 and MWL1. The main word lines may be alternatively referred to as global word lines. More specifically, SWDs 610, 612, 614, and 616 (i.e., even numbered SWDs) are each coupled to main word line MWL0, and SWDs 611, 613, 615, and 617 (i.e., odd numbered SWDs) are each coupled to the main word line MWL1. The main word lines may be driven by a corresponding main word line driver MWD (not shown). In one or more examples, the MWD that drives the main word line MWL0 may be different from the MWD that drives the main word line MWL1.

In one or more examples, the word lines WL0, WL2, WL4, and WL6 corresponding to SWDs 610, 612, 614, and 616, respectively, and to the main word line MWL0 are interleaved with the word lines WL1, WL3, WL5, and WL7 corresponding to SWDs 611, 613, 615, and 617, respectively, and to the main word line MWL1 in memory cell MAT 652. Stated another way, word lines from a first set comprising the word lines WL0, WL2, WL4, and WL6 alternate with word lines from a second set comprising the word lines WL1, WL3, WL5, and WL7, such that the word lines WL0, WL2, WL4, and WL6 of the first set are positioned every other word line in memory cell MAT 652. Stated even another way, the word lines WL0, WL2, WL4, and WL6 of the first set are interleaved with the word lines WL1, WL3, WL5, and WL7 of the second set, such that two of the word lines WL1, WL3, WL5, and WL7 of the second set (e.g., the word lines WL1 and WL3) flank opposite sides of one of the word lines WL0, WL2, WL4, and WL6 of the first set (e.g., the word line WL2) and are positioned immediately adjacent the one of the word lines WL0, WL2, WL4, and WL6 of the first set. In other words, the word lines WL0-WL7 of FIG. 6A are positioned in memory cell MAT 652 such that each of the word lines WL0, WL2, WL4, and WL6 of the first set are positioned immediately adjacent at least one of the word lines WL1, WL3, WL5, and WL7 of the second set, and vice versa. In one or more examples, the use of two main word lines and the interleaved positioning of the word lines WL0-WL7 may enable shielding of floating ones of the word lines WL0-WL7 while another one of the word lines WL0-WL7 is selected and fired.

SWDs 610-617 of FIG. 6A each include a single (e.g., only one) transistor 620-627. In one or more examples, each of SWDs 610-617 only includes a single transistor. In one or more examples, each of SWDs 610-617 includes a single transistor and may include other components (not shown) that are not transistors. In the example of FIG. 6A, transistors 620-627 are MOSFET transistors. In one or more examples, transistors 620-627 are NMOS transistors.

Referring to sub-word line driver 614 as an example, sub-word line driver 614 includes a single NMOS transistor 624. The NMOS transistor 624 includes a gate coupled to the phase signal line PH4 and configured to receive a phase voltage signal driven onto the phase signal line PH4 by a corresponding FXD (not shown). The NMOS transistor 624 further includes a source coupled to word line WL4 and a drain coupled to the main word line MWL0.

Again, use of a single transistor to selectively couple a corresponding word line to a corresponding global word line in each of sub-word line drivers 610-617 may reduce the amount of space occupied or consumed by each of the sub-word line drivers 610-617 in comparison to a sub-word line driver that includes multiple transistors to selectively couple a word line to a main word line. In one or more examples, the reduction of the footprints of the sub-word line driver 610-617 may contribute to realizing a smaller size (e.g., a smaller chip size) of the overall memory device (e.g., memory device 200 of FIG. 2). Additionally, or alternatively, use of a single transistor to selectively couple a corresponding word line to a corresponding main word line enables use of a single (e.g., only one) phase driver FXD to selectively activate the single transistor. Such a configuration may help reduce the power consumption of a memory device in comparison to memory devices employing sub-word line drivers that each incorporate multiple transistors and that are each coupled to multiple phase drivers to selectively activate those transistors. As the configuration utilizes a single FX signal per sub-word line driver, the size of memory array and/or the size of the overall memory device may be reduced in comparison to memory arrays and memory devices that employ multiple FX signals per sub-word line driver.

The selection of a SWD from SWDs 610-617, and thus a selection of a corresponding word line from the word lines WL0-WL7, is determined by the voltage driven onto the phase signal lines PH0-PH7 and the voltages driven onto the main word lines MWL0 and MWL1. Referring to sub-word line driver 614 again as an example, a voltage driven onto the phase signal line PH4 may be used to switch (e.g., selectively activate or deactivate) the NMOS transistor 624. As a specific example, the FXD corresponding to the phase signal line PH4 may set a voltage on the phase signal line PH4 at a low state (e.g., VNWL, VSS, VOFF, or another low voltage value), which may deactivate NMOS transistor 624 and leave the corresponding word line WL4 floating. As another specific example, the FXD corresponding to the phase signal line PH4 may set a voltage on the phase signal line PH4 at a high state (e.g., VCC, VCCP, VCCP2, or another high voltage value) or at an intermediate state (e.g., VDRV or another intermediate voltage value), which may activate NMOS transistor 624. When NMOS transistor 624 is activated, the voltage on the word line WL4 follows (e.g., is pulled up to, is pulled down to, or remains at) a voltage on the main word line MWL0. In some embodiments, the FXD may set the voltage on the phase signal line PH4 to the high state when the word line WL4 is selected and fired for memory operations, and may set the voltage on the phase signal line PH4 to the intermediate state when the word line WL4 (or other word lines coupled to the main word line MWL0) is used to shield floating words lines coupled to the main word line MWL1. The other sub-word line drivers 610-613 and 615-617 may be operated in a manner similar to and consistent with the discussion of sub-word line driver 614 above.

The voltages on the main word lines MWL0 and MWL1 may be set at a low state (e.g., VNWL, VSS, VOFF, or another low voltage value) or at a high state (e.g., VCC, VCCP, VCCP2, or another high voltage value). Thus, referring to sub-word line driver 614, when the voltage on the phase signal line PH4 is set at the high state or at the intermediate state, the voltage on the word line WL4 may be set at a low state (e.g., VNWL, VSS, VOFF, or another low voltage value) or at a high state (e.g., VCC, VCCP, VCCP2, or another high voltage value), depending on the voltage on the main word line MWL0. As discussed in greater detail below, the voltage on the word line WL4 may be set at the high state when the word line WL4 is selected and fired. When the word line WL4 is selected and fired (e.g., when transistor 624 is activated and a voltage on the word line WL4 is set at the high state), memory cells (not shown) corresponding to the word line WL4 may be accessed for memory operations (e.g., read, write, erase, refresh, etc.) based at least in part on the voltage on the main word line MWL0. Additionally, or alternatively, the voltage on the word line WL4 may be set at the low state, for example, when an adjacent word line (e.g., either the word line WL3 or the word line WL5) is selected and fired, and the word line WL4 is used to shield a floating word line (e.g., the other of the word line WL3 or the word line WL5 that is not selected and fired).

A method of operating sub-word line drivers 610-617 to select and fire the word line WL4 is now described in an example operating scenario. An initial state of the signals is first described. At a time t0, a voltage on each of the phase signal lines PH0-PH7 is initially set at an intermediate state (e.g., a voltage VDRV, or 1.9 volts). The voltage on each of the main word lines MWL0 and MWL1 is set at a low state (e.g., VNWL, or −0.15 volts). Setting the voltages on all of the phase signal lines PH0-PH7 to the intermediate state activates all of transistors 620-627 corresponding to sub-word line drivers 610-617. As such, the word lines WL0-WL7 are each coupled to a corresponding one of the main word lines MWL0 and MWL1 via a corresponding one of the transistors 620-627. In turn, the voltage on each of the word lines WL0-WL7 follows the voltage on the corresponding one of the main word lines MWL0 and MWL1. As mentioned above, the voltage on each of the main word lines MWL0 and MWL1 is set at the low state. As a result, the voltage on each of the word lines WL0-WL7 is also initially set at the low state (e.g., VNWL, or −0.15 volts).

At a time t1, the word line WL4 is selected for memory operations. In particular, the voltage on the phase signal line PH4 is ramped to a high state (e.g., VCCP2, or 4.2 volts) to activate transistor 624 of sub-word line driver 614 corresponding to the word line WL4. At the same time, the transistors of all other sub-word line drivers that are coupled to a same main word line as the sub-word line driver corresponding to the selected word line are deactivated. Thus, sub-word line drivers 610, 612, and 616 are each coupled to the same main word line (e.g., main word line MWL0) as sub-word line driver 614 that corresponds to the selected word line WL4. Therefore, in the illustrated example, the voltages on the phase signal lines PH0, PH2, and PH6 corresponding to sub-word line drivers 610, 612, and 616 are dropped to a low state (e.g., the voltage VNWL, or −0.15 volts) to deactivate transistors 620, 622, and 626.

The high voltage on the signal line PH4 keeps transistor 624 of sub-word line driver 614 activated such that the word line WL4 continues to follow the voltage on the main word line MWL0. The low voltages on the phase signal lines PH0, PH2, and PH6 deactivates transistors 620, 622, and 626, respectively, of sub-word line drivers 610, 612, and 616, respectively. Thus, the word lines WL0, WL2, and WL6 corresponding to the sub-word line drivers WL0, WL2, and WL6, respectively, are uncoupled from the main word line MWL0 and are left floating. The voltages on the phase signal lines PH1, PH3, PH5, and PH7 and the voltage on the main word line MWL1 (and therefore the voltages on the word lines WL1, WL3, WL5, and WL7) remain unchanged from time to.

At a time t2, the voltage on the main word line (e.g., the main word line MWL0) corresponding to the selected word line (e.g., the word line WL4) is ramped to a high state (e.g., a voltage VCCP, or 3.1 volts). Because transistor 624 of sub-word line driver 614 is activated via the high voltage on the phase signal line PH4 such that the word line WL4 is coupled to the main word line MWL0 via transistor 624, the voltage on the word line WL4 follows the voltage on the main word line MWL0 from time t1 to a time t4. Thus, as the voltage on the main word line MWL0 is ramped to the high state at time t2, the voltage on the word line WL4 is also ramped to the high state (e.g., voltage VCCP, or 3.1 volts).

During time period between time t1 and time t4, the word lines WL0, WL2, and WL6 remain floating, so the voltages on those word lines do not change even as the voltage on the main word line MWL0 is ramped at time t2. In addition, the voltages on the phase signal lines PH1, PH3, PH5, and PH7 and the voltage on the main word line MWL1 remain unchanged. Thus, the voltages on the word lines WL1, WL3, WL5, and WL7 remain at the low state (e.g., VNWL, or −0.15 volts).

FIG. 6B is the schematic diagram of word line circuitry 600 of FIG. 6A in a state of operation that corresponds to the time between time t2 and time t3 described above. As shown, the low voltages (e.g., VNWL, or −0.15 volts) on the phase signal lines PH0, PH2, and PH6 have deactivated transistors 620, 622, and 626, and have left the word lines WL0, WL2, and WL6 floating (as shown using dashed lines in FIG. 6B). In addition, the intermediate voltages (e.g., VDRV, or 1.9 volts) on the phase signal lines PH1, PH3, PH5, and PH7 have activated transistors 621, 623, 625, and 627, allowing the voltages on the word lines WL1, WL3, WL5, and WL7 to follow the voltage (e.g., VNWL, or −0.15 volts) on the main word line MWL1. Furthermore, the high voltage (e.g., VCCP2, or 4.2 volts) on the phase signal line PH4 has activated the transistor 624 of the sub-word line driver 614, coupling the word line WL4 to the main word line MWL0. Therefore, as the main word line MWL0 is ramped to the high state (e.g., VCCP, or 3.1 volts) at time t2, the voltage on the word line WL4 follows, and the word line WL4 is fired.

The word lines WL1, WL3, WL5, and WL7 that are coupled to the main word line MWL1 are interleaved with the word lines WL0, WL2, WL4, and WL6 that are coupled to the main word line MWL0. Thus, the word lines WL1, WL3, WL5, and WL7 are positioned immediately adjacent one of the floating word lines WL0, WL2, and WL6. In addition, each of the word lines WL1, WL3, WL5, and WL7 are positioned between at least one of the floating word lines WL0, WL2, and WL6 and the word line WL4. Such an arrangement allows the word lines WL1, WL3, WL5, and WL7 to shield immediately adjacent ones of the floating word lines WL0, WL2, and WL6 from coupling noise with the word line WL4 as the word line WL4 is fired (e.g., as the voltage on the word line WL4 is ramped to the high state, VCCP or 3.1 volts). For example, as the word line WL4 is fired, the word line WL3 (being at the low state, VNWL or −0.15 volts) may shield the floating word line WL2 from the word line WL4. More specifically, the word line WL3 may shield the floating word line WL2 from coupling noise caused, for example, by a parasitic capacitance 657.

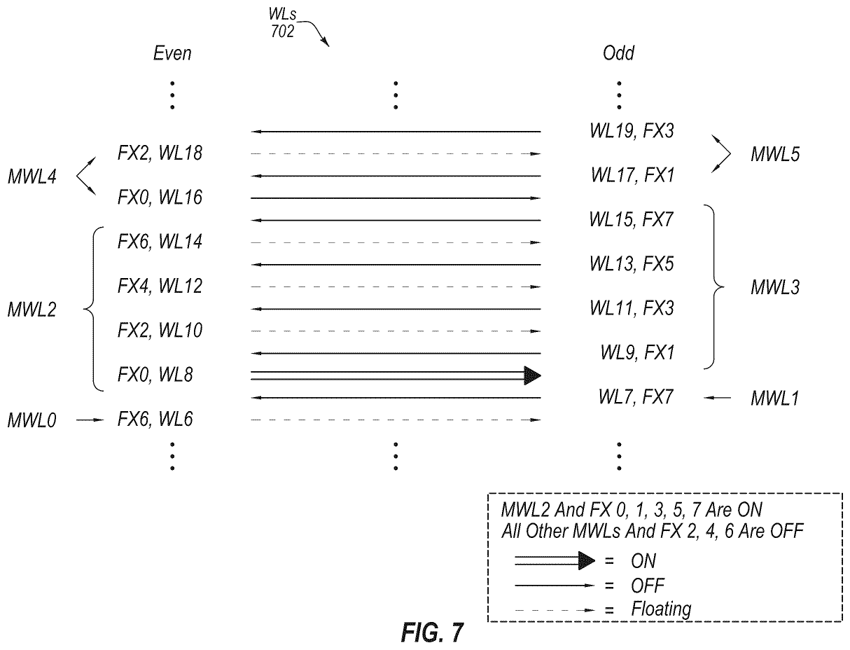

FIG. 7 is a diagram indicating various states of a number word lines WLs 702 in an example operating scenario according to one or more examples. In FIG. 7, the number of word lines WLs 702 includes, on a left side (“even” side) of the diagram, the word lines WL6, WL8, WL10, WL12, WL14, WL16, and WL18, and on a right side (e.g., “odd” side) of the diagram, the word lines WL7, WL9, WL11, WL13, WL15, WL17, and WL19. The (even) word lines WL6, WL8, WL10, WL12, WL14, WL16, and WL18 are interleaved the (odd) word lines WL7, WL9, WL11, WL13, WL15, WL17, and WL19.

On the left side (e.g., “even” side) of FIG. 7, an SWD transistor associated with the word line WL6 is driven by a phase signal line FX6 and is coupled to a main word line MWL0. An SWD transistor associated with the word line WL8 is driven by a phase signal line FX0, an SWD transistor associated with the word line WL10 is driven by a phase signal line FX2, an SWD transistor associated with the word line WL12 is driven by a phase signal line FX4, an SWD transistor associated with the word line WL14 is driven by the phase signal line FX6, and each one of these SWD transistors is coupled to a main word line MWL2. An SWD transistor associated with the word line WL16 is driven by the phase signal line FX0 and an SWD transistor associated with the word line WL18 is driven by the phase signal line FX2, and each one of these SWD transistors is coupled to a main word line MWL4.

On the right side (e.g., “odd” side) of FIG. 7, an SWD transistor associated with the word line WL7 is driven by a phase signal line FX7 and is coupled to a main word line MWL1. An SWD transistor associated with the word line WL9 is driven by a phase signal line FX1, an SWD transistor associated with the word line WL11 is driven by a phase signal line FX3, an SWD transistor associated with the word line WL13 is driven by a phase signal line FX5, an SWD transistor associated with the word line WL15 is driven by the phase signal line FX7, and each one of these SWD transistors is coupled to a main word line MWL3. An SWD transistor associated with the word line WL17 is driven by the phase signal line FX1 and an SWD transistor associated with the word line WL19 is driven by the phase signal line FX3, and each one of these SWD transistors is coupled to a main word line MWL5.

The various states of the number word lines WLs 702 includes an ON state (e.g., high state), an OFF state (e.g., low state), and a floating state. In the example scenario of FIG. 7, the main word line MWL2 is set to a high state (e.g., ON), whereas the main word lines MWL0, MWL1, MWL3, MWL4, and MWL5 are set to a low state (e.g., OFF). In addition, the phase signal lines FX0, FX1, FX3, FX5, and FX7 are set in the high state (e.g., ON), whereas the phase signal lines FX2, FX4, and FX6 are set to the low state (e.g., OFF). As a result, the word line WL8 is set in the high state (e.g., ON) as indicated in FIG. 7 by a solid double line; the word lines WL7, WL9, WL11, WL13, WL15, WL17, and WL19, and the word line WL16, are set to the low state (e.g., OFF) as indicated in FIG. 7 by solid lines; and the word lines WL6, WL10, WL12, WL14, and WL18 are floating as indicated by dashed single line. The word lines WL7, WL9, WL11, WL13, WL15, WL17, and WL19 may serve to shield the floating, unselected word lines WL6, WL10, WL12, WL14, and WL18 from the selected and fired word line WL8. Any potential memory array defects, however, could cause some of the floating, unselected word lines WL6, WL10, WL12, WL14, and WL18 to be sourced high enough to cause data corruption.

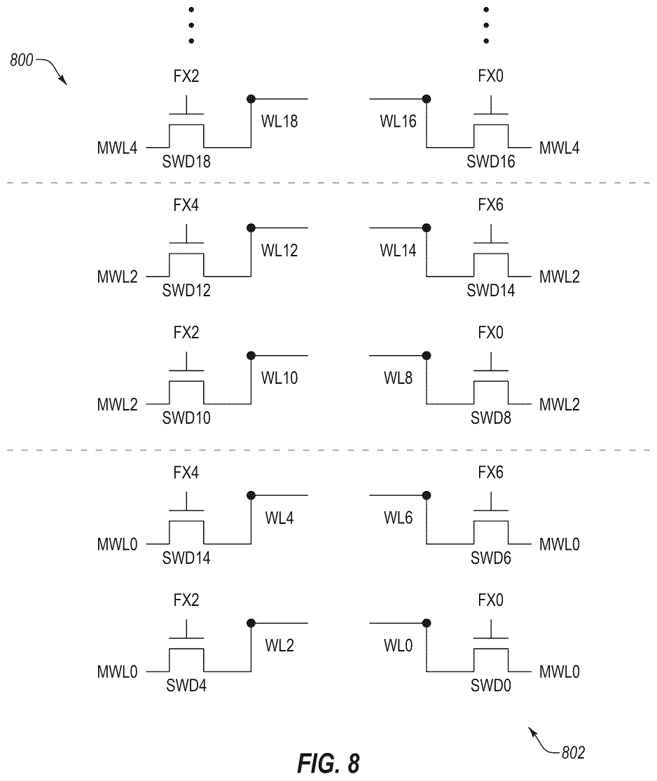

FIG. 8 is a schematic diagram of sub-word line driver (SWD) circuitry 800 which may be utilized in one or more examples of the disclosure. SWD circuitry 800 includes a number of SWD transistors 802. SWD circuitry further includes a number of word lines, a number of main word lines, and a number of phase signal lines. The number of SWD transistors 802 includes SWD transistors SWD0, SWD2, SWD4, SWD6, SWD8, SWD10, SWD12, SWD14, SWD16, and SWD18. The number of word lines include word lines WL0, WL2, WL4, WL6, WL8, WL10, WL12, WL14, WL16, and WL18. The number of main word lines includes main word lines MWL0, MWL2, and MWL4. The number of phase signal lines includes phase signal lines FX0, FX2, FX4, and FX6. Additional SWD transistors, main word lines, and word lines may be included as indicated by the ellipsis points in FIG. 8.

The SWD transistor SWD0 associated with the word line WL0 is driven by the phase signal line FX0, the SWD transistor SWD2 associated with the word line WL2 is driven by the phase signal line FX2, the SWD transistor SWD4 associated with the word line WL4 is driven by the phase signal line FX4, and the SWD transistor SWD6 associated with the word line WL6 is driven by the phase signal line FX6. Each one of these SWD transistors SWD0, SWD2, SWD4, and SWD6 is coupled to the main word line MWL0. In addition, the SWD transistor SWD8 associated with the word line WL8 is driven by the phase signal line FX0, the SWD transistor SWD10 associated with the word line WL10 is driven by the phase signal line FX2, the SWD transistor SWD12 associated with the word line WL12 is driven by the phase signal line FX4, the SWD transistor SWD14 associated with the word line WL14 is driven by the phase signal line FX6. Each one of these SWD transistors SWD8, SWD10, SWD12, and SWD14 is coupled to the main word line MWL2. Furthermore, the SWD transistor SWD16 associated with the word line WL16 is driven by the phase signal line FX0, the SWD transistor SWD18 associated with the word line WL18 is driven by the phase signal line FX2, and so on (as indicated by the ellipsis points in FIG. 8). Each one of these SWD transistors SWD16 and SWD18 is coupled to the main word line MWL4.

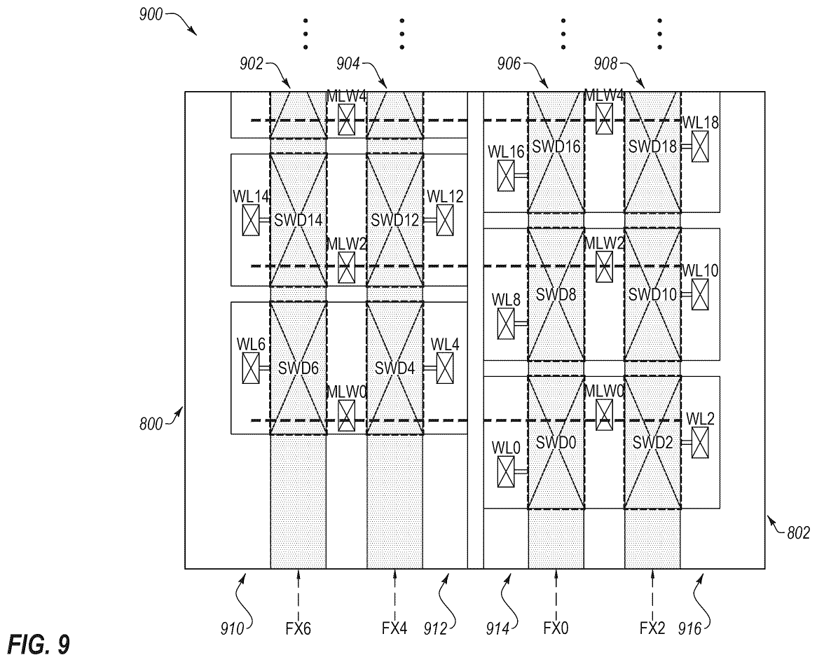

FIG. 9 is a layout 900 of SWD circuitry 800 including the number of SWD transistors 802 of FIG. 8. Layout 900 of FIG. 9 includes a number of gate areas including gate areas 902, 904, 906, and 908. In one or more examples, each one of gate areas 902, 904, 906, and 908 is formed as a vertical or columnar region in layout 900. Gate area 906 associated with phase signal line FX0 includes SWD transistor SWD0 to drive word line WL0, gate area 908 associated with phase signal line FX2 includes SWD transistor SWD2 to drive word line WL2, gate area 904 associated with phase signal line FX4 includes SWD transistor SWD4 to drive word line WL4, and gate area 902 associated with phase signal line FX6 includes SWD transistor SWD2 to drive word line WL6. The SWD transistors SWD0, SWD2, SWD4, and SWD6 are coupled to the main word line MLW0.

Gate area 906 associated with phase signal line FX0 also includes SWD transistor SWD8 to drive word line WL8, gate area 908 associated with phase signal line FX2 also includes SWD transistor SWD10 to drive word line WL10, gate area 904 associated with phase signal line FX4 also includes SWD transistor SWD12 to drive word line WL12, and gate area 902 associated with phase signal line FX6 also includes SWD transistor SWD14 to drive word line WL12. The SWD transistors SWD8, SWD10, SWD12, and SWD14 are coupled to the main word line MLW2. Gate area 906 associated with phase signal line FX0 further includes SWD transistor SWD16 to drive word line WL16, gate area 908 associated with phase signal line FX2 further includes SWD transistor SWD18 to drive word line WL18, and so on, continuing up the chain. The SWD transistors SWD16, SWD18, and others continuing up the chain (as indicated by the ellipsis points in FIG. 9), are coupled to the main word line MLW4.

Layout 900 of FIG. 9 also includes a number of connection areas including connection areas 910, 912, 914, and 916. In one or more examples, each one of connection areas 910, 912, 914, and 916 is formed as a vertical or columnar region in layout 900. Connection area 914 includes a WL0 connection region associated with the word line WL0, connection area 916 includes a WL2 connection region associated with the word line WL2, connection area 912 includes a WL4 connection region associated with the word line WL4, and connection area 910 includes a WL6 connection region associated with the word line WL6. Similarly, connection area 914 includes a WL8 connection region associated with the word line WL8, connection area 916 includes a WL10 connection region associated with the word line WL10, connection area 912 includes a WL12 connection region associated with the word line WL12, and connection area 910 includes a WL14 connection region associated with the word line WL14. Furthermore, connection area 914 includes a WL16 connection region associated with the word line WL16, connection area 916 includes a WL18 connection region associated with the word line WL18, and so on, continuing up the SWD gap (as indicated by the ellipsis points in FIG. 9). Each part of connection areas 910, 912, 914, and 916 connected to a word line WL is separated from the next connection to a word line WL by an isolating space (e.g., a shallow trench isolation (STI) region).

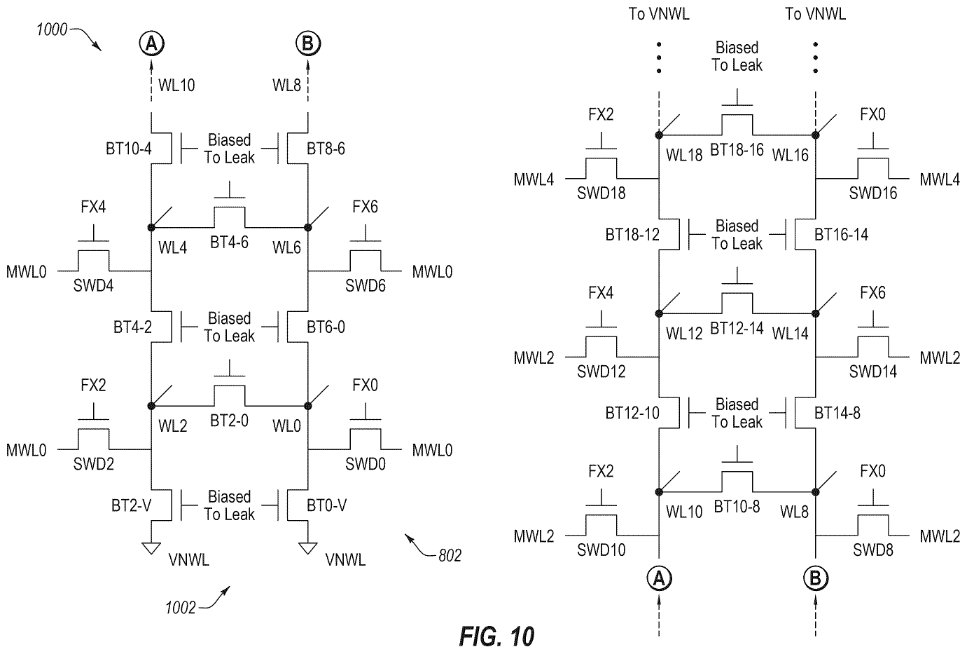

FIG. 10 is a schematic diagram of SWD circuitry 1000 including a chain of bleeder transistors 1002 according to one or more examples of the disclosure. SWD circuitry 1000 includes the number of SWD transistors 802 of FIGS. 8 and 9, which may be arranged in a similar manner as described in relation to FIGS. 8 and 9. SWD circuitry 1000 also includes the chain of bleeder transistors 1002 interconnected to word lines associated with SWD circuitry 1000. In the portion of the chain shown in FIG. 10, the chain of bleeder transistors 1002 includes bleeder transistors BT0-V, BT2-V, BT2-0, BT6-0, BT4-2, BT8-6, BT10-4, BT10-8, BT14-8, BT12-10, BT12-14, BT16-14, BT18-12, and BT18-16.

The chain of bleeder transistors 1002 are coupled to a voltage source. For example, the chain of bleeder transistors 1002 may be coupled to a voltage source at a bottom end of the chain (at a bottom, left side of the figure). In one or more examples, the voltage source is a low voltage source having a low voltage, such as a negative word line voltage (VNWL). In one or more examples, the chain of bleeder transistors 1002 is coupled to VNWL at the bottom end of the chain on each side of the chain. More specifically, bleeder transistor BT0-V includes a first terminal coupled to the word line WL0 and a second terminal coupled to VNWL, and bleeder transistor BT2-V includes a first terminal coupled to the word line WL2 and a second terminal coupled to VNWL. Each one of bleeder transistors BT0-V and BT2-V may be referred to as a terminating bleeder transistor.

Respective additional ones of the bleeder transistors in the chain may be coupled between pairs of word lines associated with adjacent SWD transistors of SWD circuitry 1000. More specifically, bleeder transistor BT2-0 includes a first terminal coupled to the word line WL2 and a second terminal coupled to the word line WL0. Bleeder transistor BT6-0 includes a first terminal coupled to the word line WL6 and a second terminal coupled to the word line WL0. Bleeder transistor BT4-2 includes a first terminal coupled to the word line WL4 and a second terminal coupled to the word line WL2. Bleeder transistor BT4-6 includes a first terminal coupled to the word line WL4 and a second terminal coupled to the word line WL6. Bleeder transistor BT8-6 includes a first terminal coupled to the word line WL8 and a second terminal coupled to the word line WL6. Bleeder transistor BT10-4 includes a first terminal coupled to the word line WL10 and a second terminal coupled to the word line WL4.

Continuing though connectors “a” and “b” in FIG. 10 (from the top left side of the figure to the bottom right side of the figure), bleeder transistor BT10-8 includes a first terminal coupled to the word line WL10 and a second terminal coupled to the word line WL8. Bleeder transistor BT14-8 includes a first terminal coupled to the word line WL14 and a second terminal coupled to the word line WL8. Bleeder transistor BT12-10 includes a first terminal coupled to the word line WL12 and a second terminal coupled to the word line WL10. Bleeder transistor BT12-14 includes a first terminal coupled to the word line WL12 and a second terminal coupled to the word line WL14. Bleeder transistor BT16-14 includes a first terminal coupled to the word line WL16 and a second terminal coupled to the word line WL14. Bleeder transistor BT18-16 includes a first terminal coupled to the word line WL18 and a second terminal coupled to the word line WL16.

As indicated by the ellipsis points in FIG. 10 (at a top, right side of the figure), the chain of bleeder transistors 1002 may include additional bleeder transistors interconnected with additional word lines associated with additional adjacent SWD transistors of SWD circuitry 1000. In addition, the chain of bleeder transistors 1002 may be coupled to the voltage source (e.g., VNWL), for example, at a top end of the chain. In one or more examples, the chain of bleeder transistors 1002 may be coupled to VNWL at the top end of the chain on each side of the chain.

Each bleeder transistor in the chain of bleeder transistors 1002 includes a gate coupled to a biasing voltage source. In one or more examples, the biasing voltage source is to produce a biasing voltage to bias each of the bleeder transistors to leak to the low voltage (e.g., VNWL). In one or more examples, the biasing voltage source is to produce a biasing voltage substantially equal to a threshold voltage Vt of the transistor for biasing each one of the bleeder transistors to leak to VNWL. In one or more examples, the threshold voltage Vt of the transistor for biasing is about 0.7 volts. In one or more examples, tuning or calibration techniques may be performed (e.g., using probe trim, tempslope, and so on) in relation to the biasing voltage to address any notable variability in process, voltage, and temperature (PVT) variations.

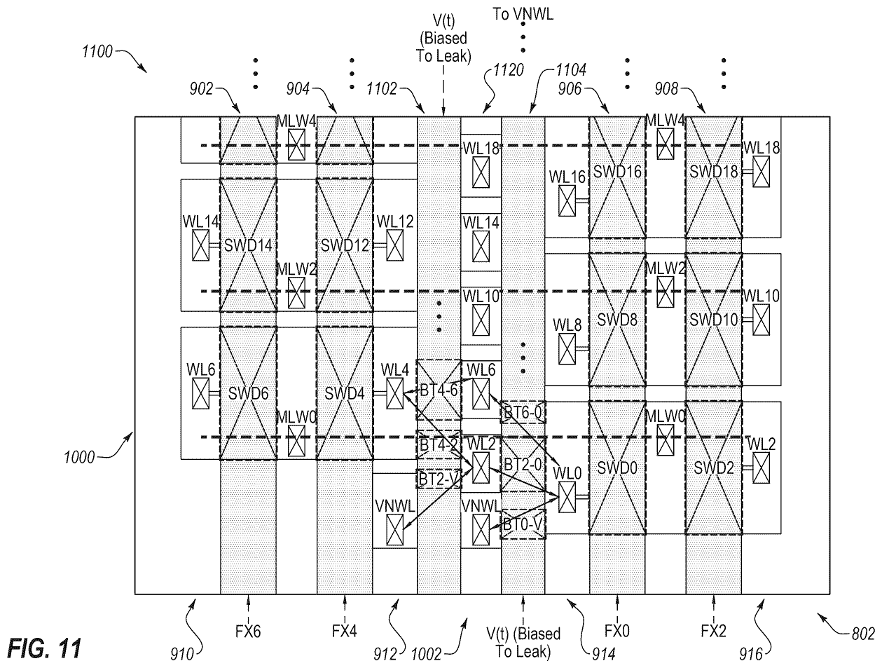

FIG. 11 is a layout 1100 of SWD circuitry 1000 including the chain of bleeder transistors 1002 of FIG. 10 according to one or more examples of the disclosure. In one or more examples, layout 1100 of SWD circuitry 1000 includes SWD transistors 802 and connection regions arranged in a similar manner as layout 900 of FIG. 9, but further including the chain of bleeder transistors 1002. To accommodate the chain of bleeder transistors 1002, layout 1100 further includes gate areas 1102 and 1104 adjacent and in between (e.g., separating) gate areas 904 and 906. In addition, a connection area 1120 is formed in between (e.g., separating) gate areas 1102 and 1104. In one or more examples, gate areas 1102 and 1104 (including connection area 1120) are formed in a substantially central region of layout 1100.

Connection area 1120 includes additional word line connection regions coupled to some of the word lines via extended connections. More specifically, connection area 1120 includes an additional WL18 connection region associated with the word line WL18 coupled via an extended connection (e.g., from right to left). Connection area 1120 includes an additional WL14 connection region associated with the word line WL14 coupled via an extended connection (e.g., from left to right). Connection area 1120 includes an additional WL10 connection region associated with the word line WL10 coupled via an extended connection (e.g., from right to left). Connection area 1120 includes an additional WL6 connection region associated with the word line WL6 coupled via an extended connection (e.g., from left to right). Connection area 1120 includes an additional WL2 connection region associated with the word line WL2 coupled via an extended connection (e.g., from right to left).

The chain of bleeder transistors 1002 may be coupled to the voltage source (e.g., VNWL) at the bottom of the chain. To achieve this coupling, connection area 912 includes a VNWL connection region associated with VNWL, and connection area 1120 includes an additional VNWL connection region associated with VNWL which is coupled via an extended connection (e.g., from right to left). The terminating bleeder transistors are used for coupling VNWL to the rest of the chain. More particularly, bleeder transistor BT0-V in gate area 1104 includes a first terminal coupled to the WL0 connection region in connection area 914 and a second terminal coupled to the VNWL connection region in connection area 1120. In addition, bleeder transistor BT2-V in gate area 1104 includes a first terminal coupled to the WL2 connection region in connection area 1120 and a second terminal coupled to the VNWL connection region in connection area 912.

Respective additional ones of the bleeder transistors in the chain are coupled between the pairs of word lines associated with adjacent SWD transistors. More specifically, bleeder transistor BT2-0 includes the first terminal coupled to the WL2 connection region in connection area 1120 and the second terminal coupled to the WL0 connection region in connection area 914. Bleeder transistor BT6-0 includes the first terminal coupled to the WL6 connection region in connection area 1120 and the second terminal coupled to the WL0 connection region in connection area 914. Bleeder transistor BT4-2 includes the first terminal coupled to the WL4 connection region in connection area 912 and the second terminal coupled to the WL2 connection region in connection area 1120. Bleeder transistor BT4-6 includes the first terminal coupled to the WL4 connection region in connection area 912 and the second terminal coupled to the WL6 connection region in connection area 1120. As indicated by the ellipsis points in FIG. 11, the chain of bleeder transistors 1002 may include the other bleeder transistors interconnected with the word lines associated with additional adjacent SWD transistors of SWD circuitry 1000. In addition, the chain of bleeder transistors 1002 may be coupled to the voltage source (e.g., VNWL) at the top end of the chain.

In one or more examples, the biasing voltage source is to produce a biasing voltage (e.g., the threshold voltage Vt) to bias each of the bleeder transistors to leak to VNWL. In layout 1100 of FIG. 11, the gates to bias bleeder transistors BT0-V, BT2-0, BT6-0, BT8-6, BT10-8, BT14-8, BT16-14, and BT18-16 are in gate area 1104, and the gates to bias bleeder transistors BT2-V, BT4-2, BT4-6, BT10-4, BT12-10, BT12-14, and BT18-12 are in gate area 1102.

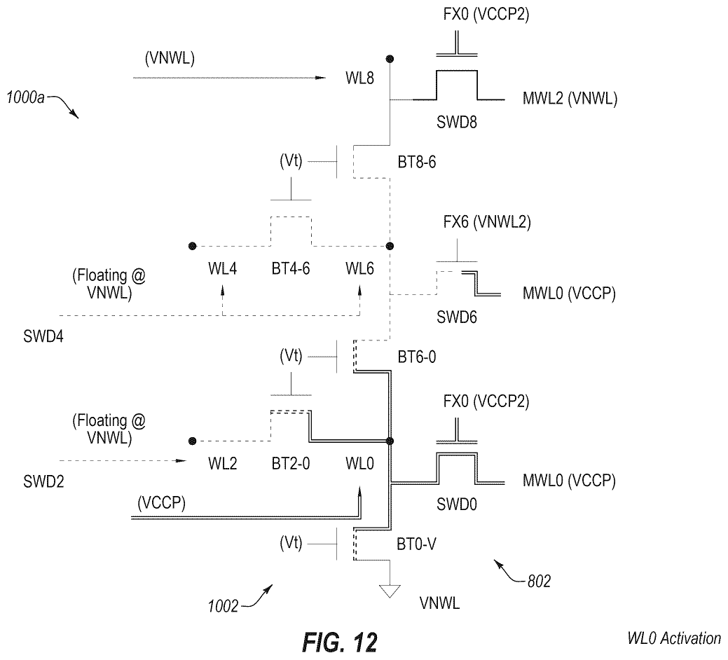

FIG. 12 is a circuit portion 1000a of SWD circuitry 1000 of FIG. 10 in an example operating scenario according to one or more examples of the disclosure. Circuit portion 1000a shown in FIG. 12 includes some of SWD transistors 802 of FIG. 10 (e.g., SWD0 transistor, SWD2 transistor, SWD4 transistor, and SWD6 transistor) and some of the chain of bleeder transistors 1002 of FIG. 10 (e.g., bleeder transistor BT0-V, bleeder transistor BT2-0, bleeder transistor BT6-0, bleeder transistor BT4-6, and bleeder transistor BT-8-6). Circuit portion 1000a represents an example circuit portion of SWD circuitry 1000 of FIG. 10 for describing the example operating scenario; the example operating scenario is repeatable for other circuit portions of SWD circuitry of FIG. 10. In FIG. 12, line portions in “double line” format indicate connections at the high voltage state (e.g., VCCP), line portions in “single line” format indicate connections at the low voltage state (e.g., VNWL), and line portions in “single dashed line” format indicate connections floating but maintained at the low voltage state (e.g., VNWL).

In the example operating scenario, SWD0 transistor is turned on to activate word line WL0. To activate word line WL0, the voltage on the main word line MWL0 is set to a high state (e.g., VCCP) and the voltage of the phase signal line FX0 is set to a high state (e.g., VCCP2). As the main word line MWL0 is at the high state and the SWD0 transistor is switched to turn on (FX0=high state), the word line WL0 is set to the high state voltage of the main word line MWL0 (i.e., VCCP). The voltages on the other main word lines (e.g., main word line MWL2) are set to the low state (e.g., VNWL), and the voltages on the other phase signal lines (e.g., phase signal lines FX2, FX4, and FX6) are set to the low state (e.g., VNWL2). As the main word line MWL2 is at the low state voltage and SWD8 transistor is switched to turn on (FX0=high state), the word line WL8 is set to the low state voltage of the main word line MWL2 (e.g., VNWL).

As the SWD2 transistor, the SWD4 transistor, and the SWD6 transistor are off, the word line WL2, the word line WL4, and the word line WL6 are to float. However, bleeder transistors BT8-6, BT4-6, BT6-0, BT2-0, and BT0-V, each of which is biased to leak to VNWL, will maintain the voltage of the floating word lines at VNWL.

More particularly, the word line WL8 is set to the low state voltage of the main word line MWL2 (i.e., VNWL). As the word line WL6 is coupled to the word line WL8 via bleeder transistor BT8-6, the voltage of word line WL6 is maintained at VNWL. As the word line WL4 is coupled to the word line WL6 via bleeder transistor BT4-6, the voltage of word line WL4 is also maintained at VNWL. As the word line WL2 is coupled to the word line WL4 via bleeder transistor BT4-2 (not shown in FIG. 12) and coupled to VNWL via bleeder transistor BT2-V (not shown in FIG. 12), the voltage of word line WL2 is also maintained at VNWL.

Although the word line WL6 is coupled to the word line WL0 (at VCCP) via bleeder transistor BT6-0, the word line WL6 will remain at the low state (e.g., VNWL) since the leakage to VNWL will dominate over the leakage to VCCP. In or more examples, bleeder transistors connected to an active word line are maintained in a high drain-to-source voltage (i.e., high V_{ds}), low gate-to-source voltage (i.e., low V_{gs}).

In one or more examples, the technology of the disclosure improves the performance and/or reliability of the single-transistor, sub-word line driver circuitry, or variations of such circuitry. The bleeder transistors serve to maintain otherwise floating word lines at the low voltage to ensure that any memory array defects or other influences do not adversely affect the voltages on the word lines (e.g., causing data corruption). The use of transistors (e.g., in contrast to resistors) to provide leaking or bleeding is advantageous for minimizing the amount of space utilized. The bleeder transistors may be easily accommodated in the layout using only a few additional gate areas and/or other layout areas.

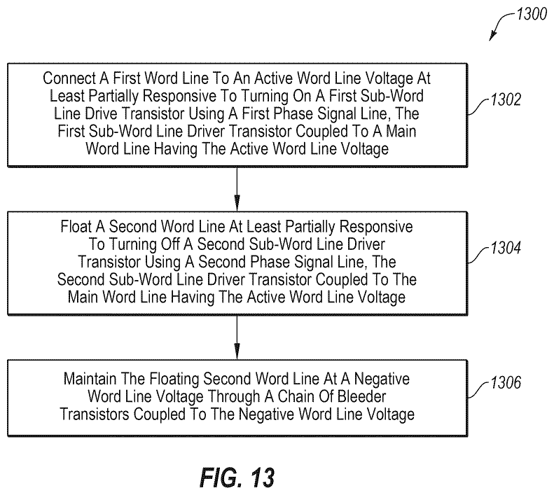

FIG. 13 is a flowchart of a method 1300 of operating SWD circuitry according to one or more examples. Method 1300 may be performed with use of SWD circuitry 1000 of FIGS. 10 and 11, and/or circuit portion 1000a of FIG. 12, in one or more examples.

Beginning at act 1302, a first word line is connected to an active word line voltage (e.g., VCCP) at least partially responsive to turning on a first sub-word line driver transistor using a first phase signal line. The first sub-word line driver transistor is coupled to a main word line having the active word line voltage. At an act 1304, a second word line is floated at least partially responsive to turning off a second sub-word line driver transistor using a second phase signal line. The second sub-word line driver transistor is coupled to the main word line having the active word line voltage. At an act 1306, the floating second word line is maintained at a negative word line voltage or VNWL through a chain of bleeder transistors. In one or more examples, the chain of bleeder transistors may be interconnected with the word lines and coupled to the negative word line voltage.

In one or more examples, method 1300 may include biasing, at a threshold voltage, each one of the bleeder transistors to leak to the negative word line voltage.

In one or more examples, method 1300 may include maintaining the second word line at the negative word line voltage via the chain of bleeder transistors including a terminating bleeder transistor. The terminating bleeder transistor may be coupled between the first word line and the negative word line voltage.

In one or more examples, method 1300 may include connecting the negative word line voltage to a third word line at least partially responsive to turning on a third sub-word line driver transistor using the first phase signal line. The third sub-word line driver may be coupled to another main word line having the negative word line voltage. In one or more examples, method 1300 may further include maintaining the third word line at the negative word line voltage via the chain of bleeder transistors.

In one or more examples of method 1300, each sub-word line driver of the number of sub-word line drivers includes a single transistor.

A memory device is also disclosed. According to one or more examples, the memory device may include one or more memory cell arrays, such as memory array 250 (see FIG. 2). The one or more memory cell arrays may include a number of memory cells.

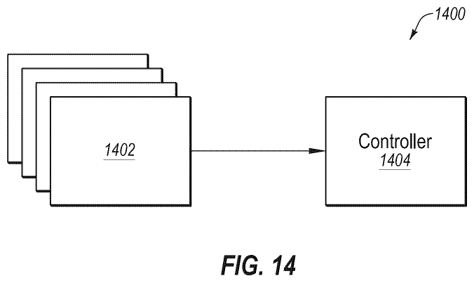

FIG. 14 is a simplified block diagram of a memory device 1400 implemented according to one or more examples described herein. Memory device 1400, which may include, for example, a semiconductor device, includes a memory array 1402 and a controller 1404. Memory array 1402, which may include a number of memory banks, may include a number of memory cells. Controller 1404 may be operatively coupled with memory array 1402 so as to read, write, or refresh any or all memory cells within memory array 1402. Controller 1404 may be configured for carrying out one or more embodiments disclosed herein. For example, in some embodiments, controller 1404 may include at least a portion of, for example, SWD circuitry 1000 of FIG. 10, layout 1100 of SWD circuitry 1000 of FIG. 11, and/or circuit portion 1000a of FIG. 12.

A system is also disclosed. According to one or more examples, the system may include a memory device including a number of memory banks, each memory bank having an array of memory cells. Each memory cell may include an access transistor and a storage element operably coupled with the access transistor.

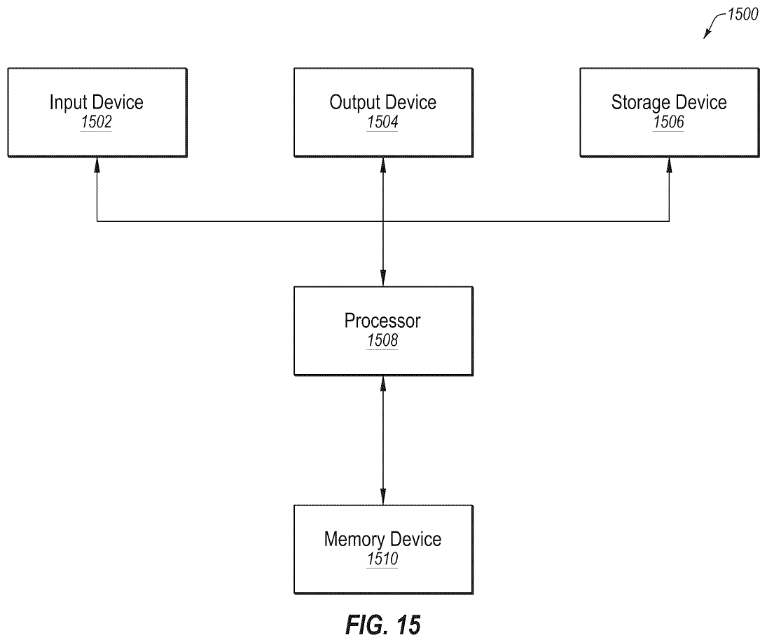

FIG. 15 is a simplified block diagram of an electronic system 1500 implemented according to one or more examples described herein. Electronic system 1500 includes at least one input device 1502, which may include, for example, a keyboard, a mouse, or a touch screen. Electronic system 1500 further includes at least one output device 1504, such as a monitor, a touch screen, or a speaker. Input device 1502 and output device 1504 are not necessarily separable from one another. Electronic system 1500 further includes a storage device 1506. Input device 1502, output device 1504, and storage device 1506 may be coupled to a processor 1508. Electronic system 1500 further includes a memory device 1510 coupled to processor 1508. Memory device 1510, which may include memory device 200 of FIG. 2, may include an array of memory cells. Electronic system 1500 may include, for example, a computing, processing, industrial, or consumer product. For example, without limitation, electronic system 1500 may include a personal computer or computer hardware component, a server or other networking hardware component, a database engine, an intrusion prevention system, a handheld device, a tablet computer, an electronic notebook, a camera, a phone, a music player, a wireless device, a display, a chip set, a game, a vehicle, or other known systems.

As used herein, the terms “memory device” and “memory system” refer to devices and systems configured to temporarily and/or permanently store information related to various electronic devices. Accordingly, the term “memory device” may refer to a single memory die and/or to a memory package containing one or more memory dies. Similarly, the term “memory system” may refer to a system including one or more memory dies (e.g., a memory package) and/or to a system (e.g., a dual in-line memory module (DIMM)) including one or more memory packages.

In accordance with common practice, the various features illustrated in the drawings may not be drawn to scale. The illustrations presented in the present disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

As used herein, the term “device” or “memory device” may include a device with memory but is not limited to a device with only memory. For example, a device or a memory device may include memory, a processor, and/or other components or functions. For example, a device or memory device may include a system on a chip (SOC).

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

A non-exhaustive, non-limiting list of examples follows. Note that each of the examples listed below is explicitly and individually indicated as being combinable with all others of the examples listed below and examples discussed above. It is intended, however, that these examples are combinable with all other examples unless it would be apparent to one of ordinary skill in the art that the examples are not combinable.

Additional non-limiting examples of the disclosure include:

Example 1: A device comprising: a number of word lines; a number of sub-word line drivers, each sub-word line driver coupled to a main word line and a respective word line of the number of word lines, each sub-word line driver including a transistor; a number of phase signal lines, each phase signal line coupled to a respective gate of a respective transistor of a respective sub-word line driver of the number of sub-word line drivers; and a chain of bleeder transistors, the chain of bleeder transistors interconnected with the word lines and coupled to a negative word line voltage.

Example 2: The device according to Example 1, wherein the chain of bleeder transistors are biased to leak to the negative word line voltage to maintain floating word lines at the negative word line voltage.

Example 3: The device according to any of Examples 1 and 2, wherein respective ones of at least some of the bleeder transistors are coupled between respective pairs of word lines associated with adjacent sub-word line drivers of the number of sub-word line drivers.

Example 4: The device according to any of Examples 1-3, wherein the chain of bleeder transistors includes a terminating bleeder transistor coupled between one of the word lines and the negative word line voltage.

Example 5: The device according to any of Examples 1-4, wherein a respective sub-word line driver is configured to, in response to receipt of an activation signal via a respective phase signal line when the main word line is activated, couple a respective word line to the main word line.

Example 6: The device according to any of Examples 1-5, wherein respective other sub-word line drivers are configured to, in response to a deactivation signal via respective other phase signal lines when the main word line is activated, float respective other word lines of the number of word lines.

Example 7: The device according to any of Examples 1-6, comprising: a number of additional sub-word line drivers, each additional sub-word line driver coupled to an additional main word line and a respective word line of the number of word lines, each additional sub-word line driver including a transistor, wherein each phase signal is further coupled to a respective gate of a respective transistor of a respective additional sub-word line driver of the number of additional sub-word line drivers, and wherein respective additional ones of the at least some of the bleeder transistors are coupled between respective additional pairs of word lines associated with adjacent second sub-word line drivers of the number of second sub-word line drivers and adjacent first and second sub-word line drivers.

Example 8: The device according to any of Examples 1-7, wherein each sub-word line driver of the number of sub-word line drivers includes a single transistor.

Example 9: A method comprising: connecting a first word line to an active word line voltage at least partially responsive to turning on a first sub-word line driver transistor using a first phase signal line, the first sub-word line driver transistor coupled to a main word line having the active word line voltage; floating a second word line at least partially responsive to turning off a second sub-word line driver transistor using a second phase signal line, the second sub-word line driver transistor coupled to the main word line having the active word line voltage; and maintaining the floating second word line at a negative word line voltage through a chain of bleeder transistors coupled to the negative word line voltage.

Example 10: The method according to Example 9, comprising: biasing, at a threshold voltage, each one of the bleeder transistors to leak to the negative word line voltage.

Example 11: The method according to any of Examples 9 and 10, comprising: maintaining the second word line at the negative word line voltage via the chain of bleeder transistors including a terminating bleeder transistor, the terminating bleeder transistor coupled between the first word line and the negative word line voltage.

Example 12: The method according to any of Examples 9-11, comprising: connecting the negative word line voltage to a third word line at least partially responsive to turning on a third sub-word line driver transistor using the first phase signal line, the third sub-word line driver coupled to another main word line having the negative word line voltage; and maintaining the third word line at the negative word line voltage via the chain of bleeder transistors.

Example 13: The method according to any of Examples 9-12, wherein each sub-word line driver of a number of sub-word line drivers includes a single transistor.

Example 14: A device comprising: a number of sub-word line drivers including: a first sub-word line driver to drive a first word line; a second sub-word line driver to drive a second word line; a third sub-word line driver to drive a third word line; and a fourth sub-word line driver to drive a fourth word line; and a chain of bleeder transistors coupled to a negative word line voltage, the chain of bleeder transistors including: a first bleeder transistor coupled between the first word line and the second word line; a second bleeder transistor coupled between the second word line and the third word line; a third bleeder transistor coupled between the third word line and the fourth word line; and a fourth bleeder transistor coupled between the fourth word line and the first word line.

Example 15: The device according to Example 14, wherein: the first sub-word line driver is adjacent the second sub-word line driver; the second sub-word line driver is adjacent the third sub-word line driver; the third sub-word line driver is adjacent the fourth sub-word line driver; and the fourth sub-word line driver is adjacent the first sub-word line driver.

Example 16: The device according to any of Examples 14 and 15, wherein the chain of bleeder transistors includes: a first terminating bleeder transistor coupled between the first word line and the negative word line voltage; and a second terminating bleeder transistor coupled between the second word line and the negative word line voltage.

Example 17: The device according to any of Examples 14-16, wherein the chain of bleeder transistors is biased to leak to the negative word line voltage to maintain floating word lines of the number of word lines to the negative word line voltage.

Example 18: The device according to any of Examples 14-17, wherein: the number of sub-word line drivers comprises a number of first sub-word line drivers; respective ones of the number of first sub-word line drivers coupled to a first main word line; a number of second sub-word line drivers includes: a fifth sub-word line driver to drive a fifth word line; a sixth sub-word line driver to drive a sixth word line; a seventh sub-word line driver to drive a seventh word line; and an eighth sub-word line driver to drive an eighth word line; respective ones of the number of second sub-word line drivers coupled to a second main word line; and the chain of bleeder transistors includes: a fifth bleeder transistor coupled between the third word line and the sixth word line; a sixth bleeder transistor coupled between the fourth word line and the fifth word line; a seventh bleeder transistor coupled between the fifth word line and the sixth word line; an eighth bleeder transistor coupled between the sixth word line and the seventh word line; a ninth bleeder transistor coupled between the seventh word line and the eighth word line; and a tenth bleeder transistor coupled between the eighth word line and the fifth word line.

Example 19: The device according to any of Examples 14-18, wherein each sub-word line driver of the number of first sub-word line drivers and the number of second sub-word line drivers includes a single transistor, the device comprising: a number of phase signal lines, each phase signal line coupled to a respective gate of a respective transistor of a respective sub-word line driver of the number of first sub-word line drivers, each phase signal line further coupled to a respective gate of a respective transistor of a respective sub-word line driver of the number of second sub-word line drivers.

Example 20: The device according to any of Examples 14-19, wherein: a respective sub-word line driver is configured to, in response to receipt of a signal via a respective phase signal line when the first main word line is activated and the second main word line is deactivated, couple a respective word line to the main word line; respective other sub-word line drivers are configured to float respective other ones of the word lines in response to the receipt of the signal at the respective sub-word line driver when the main word line is activated and the second main word line is deactivated; and the chain of bleeder transistors are to maintain the floating word lines of the number of word lines to the negative word line voltage.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. A device comprising:
a number of word lines;
a number of sub-word line drivers, each sub-word line driver coupled to a main word line and a respective word line of the number of word lines, each sub-word line driver including a transistor;
a number of phase signal lines, each phase signal line coupled to a respective gate of a respective transistor of a respective sub-word line driver of the number of sub-word line drivers; and
a chain of bleeder transistors, the chain of bleeder transistors interconnected with the word lines and coupled to a negative word line voltage.

2. The device of claim 1, wherein the chain of bleeder transistors are biased to leak to the negative word line voltage to maintain floating word lines at the negative word line voltage.

3. The device of claim 1, wherein respective ones of at least some of the bleeder transistors are coupled between respective pairs of word lines associated with adjacent sub-word line drivers of the number of sub-word line drivers.

4. The device of claim 3, wherein the chain of bleeder transistors includes a terminating bleeder transistor coupled between one of the word lines and the negative word line voltage.

5. The device of claim 1, wherein a respective sub-word line driver is configured to, in response to receipt of an activation signal via a respective phase signal line when the main word line is activated, couple a respective word line to the main word line.

6. The device of claim 5, wherein respective other sub-word line drivers are configured to, in response to a deactivation signal via respective other phase signal lines when the main word line is activated, float respective other word lines of the number of word lines.

7. The device of claim 3, comprising:
a number of additional sub-word line drivers, each additional sub-word line driver coupled to an additional main word line and a respective word line of the number of word lines, each additional sub-word line driver including a transistor,
wherein each phase signal is further coupled to a respective gate of a respective transistor of a respective additional sub-word line driver of the number of additional sub-word line drivers, and
wherein respective additional ones of the at least some of the bleeder transistors are coupled between respective additional pairs of word lines associated with adjacent second sub-word line drivers of the number of second sub-word line drivers and adjacent first and second sub-word line drivers.

8. The device of claim 1, wherein each sub-word line driver of the number of sub-word line drivers includes a single transistor.

9. A method comprising:
connecting a first word line to an active word line voltage at least partially responsive to turning on a first sub-word line driver transistor using a first phase signal line, the first sub-word line driver transistor coupled to a main word line having the active word line voltage;
floating a second word line at least partially responsive to turning off a second sub-word line driver transistor using a second phase signal line, the second sub-word line driver transistor coupled to the main word line having the active word line voltage; and
maintaining the floating second word line at a negative word line voltage through a chain of bleeder transistors coupled to the negative word line voltage.

10. The method of claim 9, comprising:
biasing, at a threshold voltage, each one of the bleeder transistors to leak to the negative word line voltage.

11. The method of claim 9, comprising:
maintaining the second word line at the negative word line voltage via the chain of bleeder transistors including a terminating bleeder transistor, the terminating bleeder transistor coupled between the first word line and the negative word line voltage.

12. The method of claim 11, comprising:
connecting the negative word line voltage to a third word line at least partially responsive to turning on a third sub-word line driver transistor using the first phase signal line, the third sub-word line driver coupled to another main word line having the negative word line voltage; and
maintaining the third word line at the negative word line voltage via the chain of bleeder transistors.

13. The method of claim 9, wherein each sub-word line driver of a number of sub-word line drivers includes a single transistor.

14. A device comprising:
a number of sub-word line drivers including:
a first sub-word line driver to drive a first word line;
a second sub-word line driver to drive a second word line;
a third sub-word line driver to drive a third word line; and
a fourth sub-word line driver to drive a fourth word line; and
a chain of bleeder transistors coupled to a negative word line voltage, the chain of bleeder transistors including:
a first bleeder transistor coupled between the first word line and the second word line;
a second bleeder transistor coupled between the second word line and the third word line;
a third bleeder transistor coupled between the third word line and the fourth word line; and
a fourth bleeder transistor coupled between the fourth word line and the first word line.

15. The device of claim 14, wherein:
the first sub-word line driver is adjacent the second sub-word line driver;
the second sub-word line driver is adjacent the third sub-word line driver;
the third sub-word line driver is adjacent the fourth sub-word line driver; and
the fourth sub-word line driver is adjacent the first sub-word line driver.

16. The device of claim 14, wherein the chain of bleeder transistors includes:
a first terminating bleeder transistor coupled between the first word line and the negative word line voltage; and
a second terminating bleeder transistor coupled between the second word line and the negative word line voltage.

17. The device of claim 16, wherein the chain of bleeder transistors are biased to leak to the negative word line voltage to maintain floating word lines of the number of word lines to the negative word line voltage.

18. The device of claim 16, wherein:
the number of sub-word line drivers comprises a number of first sub-word line drivers;
respective ones of the number of first sub-word line drivers coupled to a first main word line;
a number of second sub-word line drivers includes:
a fifth sub-word line driver to drive a fifth word line;
a sixth sub-word line driver to drive a sixth word line;
a seventh sub-word line driver to drive a seventh word line; and
an eighth sub-word line driver to drive an eighth word line;
respective ones of the number of second sub-word line drivers coupled to a second main word line; and
the chain of bleeder transistors includes:
a fifth bleeder transistor coupled between the third word line and the sixth word line;
a sixth bleeder transistor coupled between the fourth word line and the fifth word line;
a seventh bleeder transistor coupled between the fifth word line and the sixth word line;
an eighth bleeder transistor coupled between the sixth word line and the seventh word line;
a ninth bleeder transistor coupled between the seventh word line and the eighth word line; and
a tenth bleeder transistor coupled between the eighth word line and the fifth word line.

19. The device of claim 18, wherein each sub-word line driver of the number of first sub-word line drivers and the number of second sub-word line drivers includes a single transistor, the device comprising:
a number of phase signal lines, each phase signal line coupled to a respective gate of a respective transistor of a respective sub-word line driver of the number of first sub-word line drivers, each phase signal line further coupled to a respective gate of a respective transistor of a respective sub-word line driver of the number of second sub-word line drivers.

20. The device of claim 19, wherein:
a respective sub-word line driver is configured to, in response to receipt of a signal via a respective phase signal line when the first main word line is activated and the second main word line is deactivated, couple a respective word line to the main word line;
respective other sub-word line drivers are configured to float respective other ones of the word lines in response to the receipt of the signal at the respective sub-word line driver when the main word line is activated and the second main word line is deactivated; and
the chain of bleeder transistors are to maintain the floating word lines of the number of word lines to the negative word line voltage.
